(19) United States
(12) Patent Application Publication
(10) Pub. No.: US 2025/0293207 A1
(43) Pub. Date: Sep. 18, 2025

(54) SEMICONDUCTOR PACKAGE

(71) Applicant: Samsung Electronics Co., Ltd., Suwon-si (KR)

(72) Inventors: Gihun Lee, Suwon-si (KR); Dugjoong Kim, Suwon-si (KR); Sangmin Lee, Suwon-si (KR)

(73) Assignee: Samsung Electronics Co., Ltd., Suwon-si (KR)

(21) Appl. No.: 19/054,550

(22) Filed: Feb. 14, 2025

(30) Foreign Application Priority Data
Mar. 14, 2024 (KR) 10-2024-0035950

(51) Int. Cl. H01L 25/065; H01L 23/00; H01L 23/31; H10B 80/00

(52) U.S. Cl. CPC H01L 25/0652; H01L 24/06; H01L 24/08; H01L 24/48; H01L 23/3128; H01L 24/32; H01L 24/49; H01L 24/73; H01L 24/85; H01L 2224/06135; H01L 2224/08137; H01L 2224/32145; H01L 2224/32225; H01L 2224/48091; H01L 2224/48147; H01L 2224/48227; H01L 2224/48464; H01L 2224/49175; H01L 2224/73265; H01L 2224/8518; H01L 2224/85207; H01L 2924/1436; H01L 2924/1438; H10B 80/00

(57) ABSTRACT

A semiconductor package may include a package substrate; a lower chip stack sequentially stacked on the package substrate and including first semiconductor chips and second semiconductor chips; a first double die chip provided on the lower chip stack and including a first sub chip stacked on the first semiconductor chips, a second sub chip stacked on the second semiconductor chips, and a first connection portion; an upper chip stack sequentially stacked on the first double die chip and including third semiconductor chips sequentially stacked on the first sub chip and fourth semiconductor chips sequentially stacked on the second sub chip; a second double die chip provided on the upper chip stack and including a third sub chip stacked on the fourth semiconductor chips, a fourth sub chip stacked on the third semiconductor chips, and a second connection portion.

### CROSS REFERENCE TO RELATED APPLICATIONS

This present application claims priority to and the benefit under 35 U.S.C. § 119(a)-(d) of Korean Patent Application No. 10-2024-0035950, filed on Mar. 14, 2024, in the Korean Intellectual Property Office (KIPO), the entire disclosure of which is incorporated herein by reference.

### FIELD

Example embodiments relate to a semiconductor package including a plurality of semiconductor chips. More particularly, example embodiments relate to a semiconductor package including a plurality of single die chips and a plurality of double die chips.

### BACKGROUND

In case that a plurality of semiconductor chips are stacked on a package substrate to be offset aligned in a staircase configuration, there is a problem with a size of a semiconductor package increasing. Additionally, in case that the plurality of semiconductor chips are spaced apart from one another, a plurality of first semiconductor chips and a plurality of second semiconductor chips that are spaced apart from one another have a problem in that cracks occur due to collision between the uppermost chips. Further, in case that the number of a plurality of first semiconductor chips electrically connected to substrate pads serving as a first channel is different from the number of a plurality of second semiconductor chips electrically connected to substrate pads serving as a second channel, the semiconductor package may have electrical asymmetry. Accordingly, there is a problem that commercialization is impossible because the semiconductor package does not satisfy the joint electron device engineering council (JEDEC) standards.

### SUMMARY

Example embodiments provide a semiconductor package capable of minimizing a size of the package, preventing cracks in a semiconductor chip, and ensuring electrical symmetry.

According to example embodiments, a semiconductor package includes a package substrate providing a first side portion and a second side portion extending in a first direction to face one another, the package substrate including a plurality of first substrate pads adjacent to the first side portion and a plurality of second substrate pads adjacent to the second side portion; a first chip stack sequentially stacked on a first surface of the package substrate, wherein the first chip stack includes a plurality of first semiconductor chips electrically connected to the plurality of first substrate pads respectively by a plurality of first conductive connection members and adjacent to the first side portion of the package substrate and a plurality of second semiconductor chips electrically connected to the plurality of second substrate pads respectively by a plurality of conductive connection members and adjacent to the second side portion of the package substrate; and a first double die chip provided on the lower chip stack, wherein the first double die chip includes a first sub chip stacked on the plurality of first semiconductor chips electrically connected to the plurality of first semiconductor chips respectively by a plurality of third conductive connection members, a second sub chip stacked on the plurality of second semiconductor chips, and a first connection portion connecting the first sub chip to the second sub chip.

In embodiments, the semiconductor package further includes a second chip stack sequentially stacked on the first double die chip, wherein the second chip stack includes a plurality of third semiconductor chips sequentially stacked on the first sub chip electrically connected to the second sub chip respectively by a plurality of fourth conductive connection members and a plurality of fourth semiconductor chips sequentially stacked on the second sub chip electrically connected to the plurality of second substrate pads by a plurality of fifth conductive connection members; a second double die chip provided on the upper chip stack, wherein the second double die chip includes a third sub chip stacked on the plurality of fourth semiconductor chips electrically connected to the plurality of fourth semiconductor chips respectively by a plurality of sixth conductive connection members, a fourth sub chip stacked on the plurality of third semiconductor chips, and a second connection portion connecting the third sub chip to the fourth sub chip.

According to example embodiments, a semiconductor package includes a package substrate providing a first surface and a second surface facing one another, the package substrate having a plurality of first substrate pads and a plurality of second substrate pads provided on the first surface to be symmetrical to one another with respect to a center line; a lower chip stack including a plurality of first semiconductor chips adjacent to the plurality of first substrate pads and a plurality of second semiconductor chips adjacent to the plurality of second substrate pads, wherein the plurality of first semiconductor chips and the plurality of second semiconductor chips are sequentially stacked on the first surface of the package substrate to be symmetrical to one another with respect to the center line of the package substrate; a first double die chip stacked on the lower chip stack, wherein the first double die chip includes a first sub chip stacked on the plurality of first semiconductor chips, a second sub chip stacked on the plurality of second semiconductor chips, and a first connection portion connecting the first sub chip to the second sub chip; an upper chip stack provided on the first double die chip, wherein the upper chip stack includes a plurality of third semiconductor chips sequentially stacked on the first sub chip and a plurality of fourth semiconductor chips sequentially stacked on the second sub chip; a second double die chip stacked on the upper chip stack, wherein the second double die chip includes a third sub chip stacked on the plurality of fourth semiconductor chips, a fourth sub chip stacked on the plurality of third semiconductor chips, and a second connection portion connecting the third sub chip to the fourth sub chip; a plurality of first channel connection members electrically connecting the plurality of first substrate pads, the plurality of first semiconductor chips, the first double die chip and the plurality of third semiconductor chips; and a plurality of second channel connection members electrically connecting the plurality of second substrate pads, the plurality of second semiconductor chips, the plurality of fourth semiconductor chips and the second double die chip.

According to example embodiments, a semiconductor package includes a package substrate providing a first side portion and a second side portion extending in a first direction to face one another, the package substrate having a plurality of first substrate pads adjacent to the first side portion and a plurality of second substrate pads adjacent to the second side portion; a plurality of first semiconductor chips sequentially stacked on the package substrate to be adjacent to the first side portion of the package substrate and arranged to have an offset such that a first surface on which a plurality of first chip pads are formed faces upwardly; a plurality of second semiconductor chips sequentially stacked on the package substrate to be adjacent to the second side portion of the package substrate and arranged to have an offset such that a first surface on which a plurality of second chip pads are formed faces upwardly; a first double die chip including a first sub chip stacked on an uppermost first semiconductor chip among the plurality of first semiconductor chips such that a first surface on which a first sub chip pad is formed faces upwardly, a second sub chip stacked on an uppermost second semiconductor chip among the plurality of second semiconductor chips such that a first surface on which a second sub chip pad is formed faces upwardly, a first connection portion connecting the first sub chip to the second sub chip, and a first redistribution wirings electrically connecting the first sub chip pad to the second sub chip pad; a plurality of third semiconductor chips sequentially stacked on the first sub chip and arranged to have an offset such that a first surface on which a plurality of third chip pads are formed faces upwardly; a plurality of fourth semiconductor chips sequentially stacked on the second sub chip and arranged to have an offset such that a first surface on which a plurality of fourth chip pads are formed faces upwardly; a second double die chip including a third sub chip stacked on an uppermost fourth semiconductor chip among the plurality of fourth semiconductor chips such that a first surface on which a third sub chip pad is formed faces upwardly, a fourth sub chip stacked on an uppermost third semiconductor chip among the plurality of third semiconductor chips such that a first surface on which a fourth sub chip pad is formed faces upwardly, a second connection portion connecting the third sub chip to the fourth sub chip, and a second redistribution wirings electrically connecting the third sub chip pad to the fourth sub chip pad; a plurality of first conductive connection members electrically connecting the plurality of first substrate pads, the plurality of first chip pads and the first sub chip pad; a plurality of second conductive connection members electrically connecting the second sub chip pad and the plurality of third chip pads; a plurality of third conductive connection members electrically connecting the plurality of second substrate pads and the plurality of second chip pads; and a plurality of fourth conductive connection members electrically connecting the plurality of fourth chip pads and the third sub chip pads.

According to example embodiments, a semiconductor package may include a package substrate, a plurality of first semiconductor chips stacked on the package substrate and adjacent to a first side portion of the package substrate, a plurality of second semiconductor chips stacked on the package substrate and adjacent to a second side portion of the package substrate, a first double die chip stacked on the plurality of first semiconductor chips and the plurality of second semiconductor chips, a plurality of third semiconductor chips stacked on the first double die chip and adjacent to a first side portion of the first double die chip, a plurality of fourth semiconductor chips stacked on the first double die chip and adjacent to a second side portion of the first double die chip, and a second double die chip stacked on the plurality of third semiconductor chips and the plurality of fourth semiconductor chips.

The first double die chip may include a first sub chip, a second sub chip, and a first connection portion connecting the first sub chip to the second sub chip. The second double die chip may include a third sub chip, a fourth sub chip, and a second connection portion connecting the third sub chip to the fourth sub chip.

Accordingly, the semiconductor package may prevent cracks in semiconductor chips due to collisions between adjacent semiconductor chips.

Additionally, the plurality of first semiconductor chips and the plurality of second semiconductor chips may be stacked on the package substrate with an offset so as to be closer to a center of the package substrate. The package substrate may have a stacking region disposed between an outermost side portion of the plurality of first semiconductor chips and an outermost side portion of the plurality of second semiconductor chips. The first double die chip, the second double die chip, the plurality of third semiconductor chips, and the plurality of fourth semiconductor chips may be provided within the stacking region.

Accordingly, a size of the semiconductor package may be minimized.

Further, the package substrate of a semiconductor package may have a plurality of first substrate pads as first channels adjacent to the first side portion and a plurality of second substrate pads as second channels adjacent to the second side portion. The plurality of first substrate pads may be electrically connected to the plurality of first semiconductor chips, the first double die chip, and the plurality of third semiconductor chips. The plurality of second substrate pads may be electrically connected to the plurality of second semiconductor chips, the plurality of third semiconductor chips, and the second double die chip. In addition, a number of the plurality of first semiconductor chips may be equal to a number of the plurality of second semiconductor chips. A number of the plurality of third semiconductor chips may be equal to a number of the plurality of fourth semiconductor chips.

Accordingly, the semiconductor package may satisfy electrical symmetry.

Embodiments also are directed to a method of forming a semiconductor package, comprising: providing a package substrate having a first side portion and a second side portion extending in a first direction to face one another, and including a plurality of first substrate pads adjacent to the first side portion and a plurality of second substrate pads adjacent to the second side portion; stacking on a first surface of the package substrate a first chip stack, wherein the first chip stack includes a plurality of first semiconductor chips electrically connected to the plurality of first substrate pads respectively by a plurality of first conductive connection members and adjacent to the first side portion of the package substrate and a plurality of second semiconductor chips electrically connected to the plurality of second substrate pads respectively by a plurality of second connection members and adjacent to the second side portion of the package substrate; and providing on the first chip stack a first double die chip, the first double die chip including a first sub chip stacked on the plurality of first semiconductor chips, a second sub chip stacked on the plurality of second semiconductor chips, and a first connection portion connecting the first sub chip to the second sub chip.

### BRIEF DESCRIPTION OF THE DRAWINGS

FIG. 1 is a cross-sectional view illustrating a semiconductor package in accordance with example embodiments.

FIG. 2 is a plan view illustrating a first single die chip in FIG. 1.

FIG. 3 is a cross-sectional view taken along the line A-A′ in FIG. 1.

FIG. 4 is a cross-sectional view illustrating a seventh single die chip in FIG. 1.

FIG. 5 is a plan view illustrating a first double die chip in FIG. 1.

FIG. 6 is a cross-sectional view taken along the line B-B′ in FIG. 5.

FIG. 7 is a cross-sectional view illustrating a second double die chip in FIG. 1.

FIGS. 8 to 30 are views illustrating a method of manufacturing a semiconductor package in accordance with example embodiments.

### DETAILED DESCRIPTION

Hereinafter, example embodiments will be explained in detail with reference to the accompanying drawings.

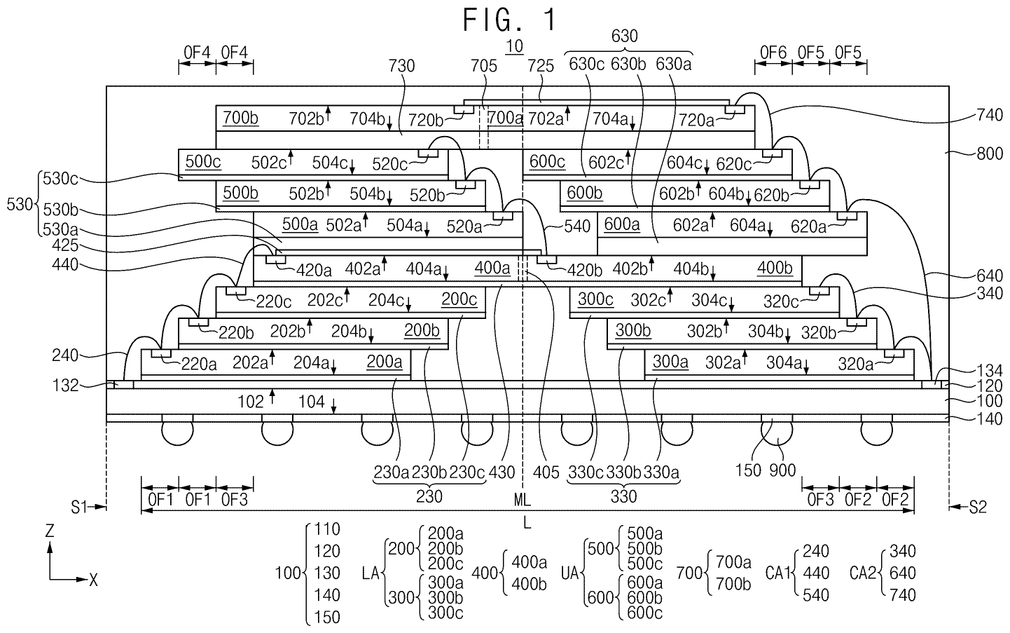

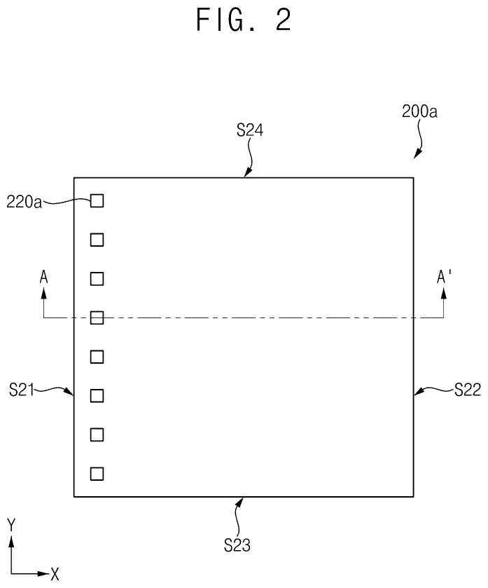

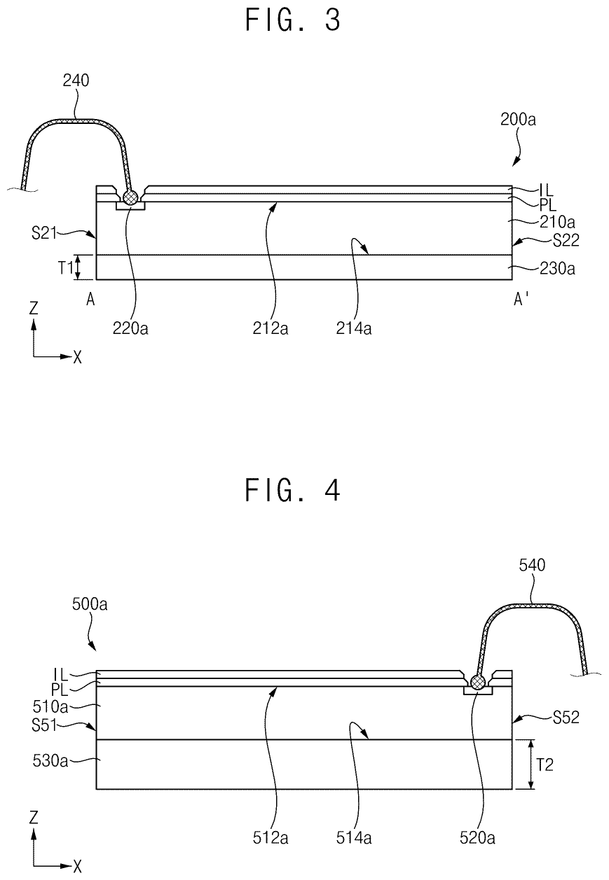

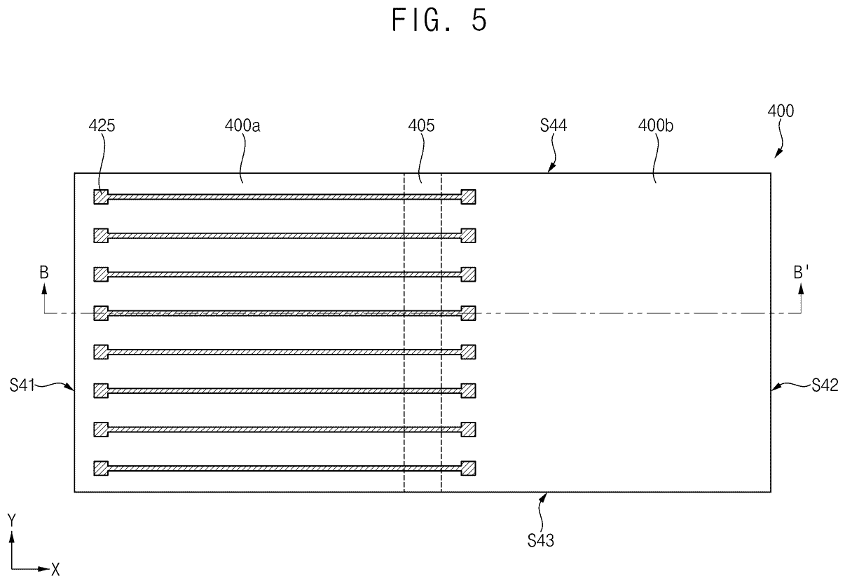

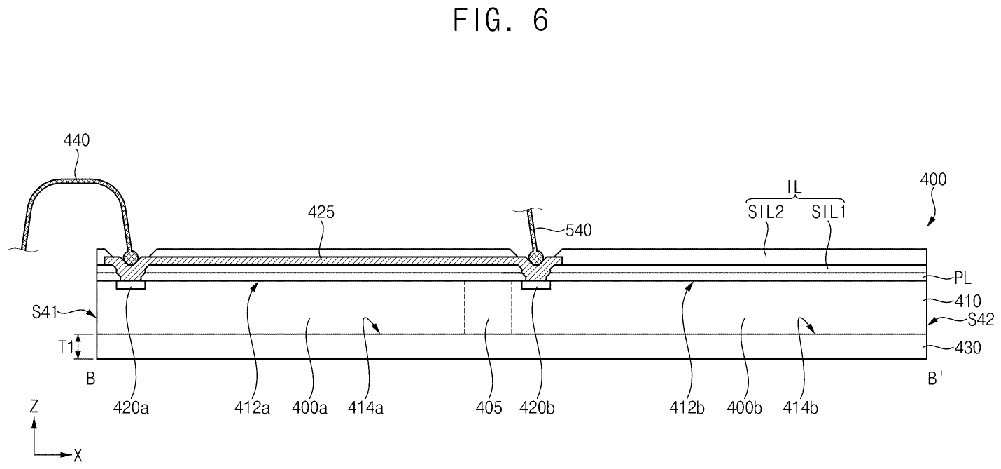

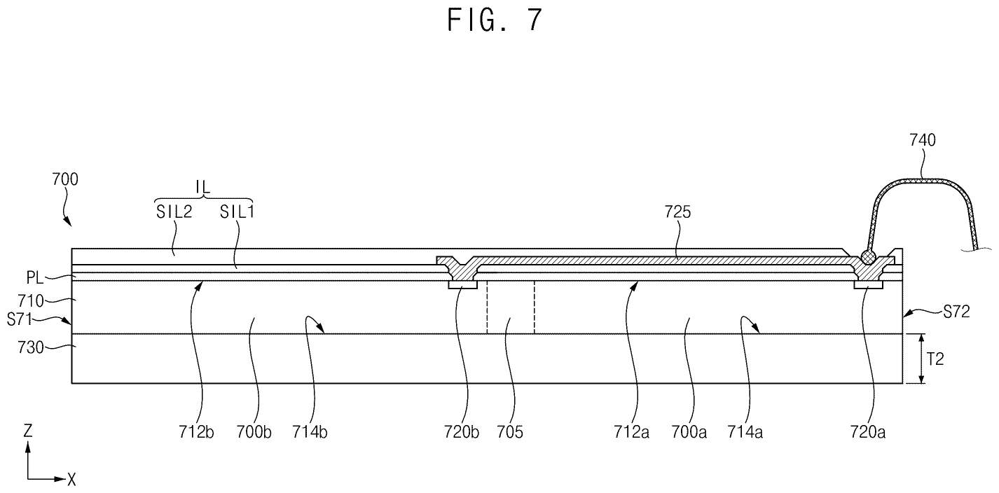

FIG. 1 is a cross-sectional view illustrating a semiconductor package in accordance with example embodiments. FIG. 2 is a plan view illustrating a first single die chip in FIG. 1. FIG. 3 is a cross-sectional view taken along the line A-A′ in FIG. 1. FIG. 4 is a cross-sectional view illustrating a seventh single die chip in FIG. 1. FIG. 5 is a plan view illustrating a first double die chip in FIG. 1. FIG. 6 is a cross-sectional view taken along the line B-B′ in FIG. 5. FIG. 7 is a cross-sectional view illustrating a second double die chip in FIG. 1.

Referring to FIGS. 1 to 7, a semiconductor package 10 may include a package substrate 100, a plurality of first semiconductor chips 200 stacked on the package substrate 100, a plurality of second semiconductor chips 300 stacked on the package substrate 100 and spaced apart from the plurality of first semiconductor chips 200 in a first direction (X direction), a first double die chip 400 stacked on the plurality of first semiconductor chips 200 and the plurality of second semiconductor chips 300, a plurality of third semiconductor chips 500 stacked on the first double die chip 400, a plurality of fourth semiconductor chips 600 stacked on the first double die chip 400 and spaced apart from the plurality of third semiconductor chips 500 in the first direction (X direction), and a second double die chip 700 stacked on the plurality of third semiconductor chips 500 and the plurality of fourth semiconductor chips 600. The semiconductor package 10 may further include a molding member 800 and a plurality of external connecting members 900.

In example embodiments, the package substrate 100 may provide a first surface 102 and a second surface 104 facing one another. The package substrate 100 may have a first side portion S1 and a second side portion S2 extending in a second direction (Y direction) perpendicular to the first direction (X direction) and facing one another. Further, the package substrate 100 may include a centerline ML provided between the first side portion S1 and the second side portion S2.

The package substrate 100 may include a first insulation layer 120 provided on the first surface 102, a plurality of first substrate pads 130 provided on the first surface 102 to be exposed from the first insulation layer 120, a second insulation layer 140 provided on the second surface 104, and a plurality of second substrate pads 150 provided on the second surface 104 to be exposed from the second insulating layer 140. The package substrate 100 may include a plurality of internal wirings that electrically connect the plurality of first substrate pads 130 and the plurality of second substrate pads 150.

The plurality of first substrate pads 130 may include a plurality of first upper substrate pads 132 adjacent to the first side portion S1 and a plurality of second upper substrate pads 134 adjacent to the second side portion S2. For example, the plurality of first upper substrate pads 132 may be provided in a region adjacent to the first side portion S1 to be arranged along the second direction (Y direction). The plurality of second upper substrate pads 134 may be provided in a region adjacent to the second side portion S2 to be arranged along the second direction (Y direction). Further, the plurality of first upper substrate pads 132 and the plurality of second upper substrate pads 134 may be symmetrical with respect to the centerline ML of the package substrate 100.

In example embodiments, each of the plurality of first semiconductor chips 200 may include a plurality of first chip pads 220a, 220b and 220c, a first die attach film 230a, 230b and 230c, and a plurality of first conductive connection members 240. In addition, each of the plurality of first semiconductor chips 200 may have a front surface as an active surface 202a, 202b and 202c and a backside surface as an inactive surface 204a, 204b and 204c. For example, the plurality of first semiconductor chips 200 may include non-volatile memory devices such as DRAM or NAND flash memory.

The plurality of first semiconductor chips 200 may be stacked sequentially on the first surface 102 of the package substrate 100 to be adjacent to the first side portion S1 of the package substrate 100. The plurality of first semiconductor chips 200 may be stacked on the first surface 102 of the package substrate 100 by the first die attach films 230a, 230b and 230c provided on the backside surface 204a, 204b and 204c.

Each of the plurality of first semiconductor chips 200 may be sequentially offset aligned such that a plurality of first chip pads 220a, 220b, 220c, which are provided on the front surface 202a, 202b, 202c, are exposed. For example, the plurality of first semiconductor chips 200 may be stacked in a cascade structure.

For example, the plurality of first semiconductor chips 200 may include first to third single die chips 200a, 200b and 200c. The first single die chip 200a as a lowermost chip may be stacked on the first surface 102 of the package substrate 100. The second single die chip 200b may be stacked on the first single die chip 200a to have a first offset OF1 from an outermost side portion of the first single die chip 200a. The third single die chip 200c may be stacked on the second single die chip 200b to have the first offset OF1 from an outermost side portion of the second single die chip 200b. The single die chip may be a semiconductor chip including a single die region of a wafer which is separated by a scribe lane region of the wafer. The die region may be a region where electronic devices such as transistors are formed on the wafer. For example, the first offset may be in a range of 250 μm to 300 μm.

The first single die chip 200a may include a first single die substrate 210a having a front surface 212a and a backside surface 214a facing one another, a plurality of chip pads 220a exposed from the front surface 212a, a die attach film 230a provided on the backside surface 214a, and a plurality of conductive connection members 240 connected to the plurality of chip pads 220a. The first single die chip 200a may have a first side portion S21 and a second side portion S22 extending in the second direction (Y direction) and facing one another. The plurality of chip pads 220a may be adjacent to the first side portion S21 and may be arranged along the first side portion S21. Further, the first single die chip 200a may include a passivation layer PL and a front insulation layer IL sequentially stacked on the front surface 212a to expose the chip pads 220a.

Although not shown in figures, the second single die chip 200b and the third single die chip 200c may be substantially identical to the first single die chip 200a. Accordingly, a detail descriptions on the second single die chip 200b and the third single die chip 200c will be omitted. Furthermore, although the figures illustrate the plurality of first semiconductor chips 200 including three single die chips, the present inventive concept is not limited thereto. Accordingly, the number of the plurality of first semiconductor chips 200 may be varied.

The plurality of first conductive connection members 240 may electrically connect the plurality of first chip pads 220a, 220b, 220c and the plurality of first upper substrate pads 132, respectively. For example, the plurality of first conductive connection members may include a plurality of conductive wires.

In example embodiments, each of the plurality of second semiconductor chips 300 may include a plurality of second chip pads 320a, 320b and 320c, a second die attach film 330a, 330b and 330c, and a plurality of second conductive connection members 340. In addition, each of the plurality of second semiconductor chips 300 may have a front surface as an active surface 302a, 302b and 302c and a backside surface as an inactive surface 304a, 304b and 304c. For example, the plurality of second semiconductor chips may include non-volatile memory devices such as DRAM or NAND flash memory.

The plurality of second semiconductor chips 300 may be stacked sequentially on the first surface 102 of the package substrate 100 to be adjacent to the second side portion S2 of the package substrate 100. The plurality of second semiconductor chips 300 may be stacked on the first surface 102 of the package substrate 100 via the second die attach films 330a, 330b and 330c provided on the backside surface 304a, 304b, 304c.

Each of the plurality of second semiconductor chips 300 may be sequentially offset aligned such that a plurality of second chip pads 320a, 320b, 320c, which is provided on the front surface 302a, 302b and 302c, are exposed. For example, the plurality of second semiconductor chips 300 may be stacked in a cascade structure.

For example, the plurality of second semiconductor chips 300 may include fourth to sixth single die chips 300a, 300b and 300c. The fourth single die chip 300a as a lowermost chip may be stacked on the first surface 102 of the package substrate 100. The fifth single die chip 300b may be stacked on the fourth single die chip 300a to have a second offset OF2 from an outermost side portion of the fourth single die chip 300a. The sixth single die chip 300c may be stacked on the fifth single die chip 300b to have the second offset OF2 from the outermost side of the fifth single die chip 300b. For example, the second offset may have the same size as the first offset. For example, the second offset may be within a range of 250 μm to 300 μm.

The fourth to sixth single die chips 300a, 300b, 300c may have a first side portion S31 and a second side portion S32 extending in the second direction (Y direction) to face one another. The plurality of second chip pads 320a, 320b, 320c may be arranged along the second side portion S32 to be adjacent to the second side portion S32.

Although not illustrated in figures, the fourth to sixth single die chips 300a, 300b and 300c may be substantially identical to the first single die chip 200a except that the plurality of second chip pads 320a, 320b, 320c are disposed adjacent to the second side portion S32. Accordingly, detail descriptions on the fourth through sixth single die chips 300a, 300b, 300c will be omitted. Further, although the figures illustrate that the plurality of second semiconductor chips 300 includes three single die chips, the present inventive concept is not limited thereto. Accordingly, the number of the plurality of second semiconductor chips 300 may be varied.

The plurality of second conductive connection members 340 may electrically connect the plurality of second chip pads 320a, 320b and 320c and the plurality of second upper substrate pads 134, respectively. For example, the plurality of second conductive connection members may be a plurality of conductive wires.

The plurality of first semiconductor chips 200 and the plurality of second semiconductor chips 300 may be stacked on the package substrate 100 to be symmetrical with respect to the centerline ML of the package substrate 100. For example, the plurality of first semiconductor chips 200 and the plurality of second semiconductor chips 300 may be stacked sequentially such that a spacing distance in the first direction (X direction) from the centerline ML gets closer and closer. Upper surfaces of each of the plurality of first semiconductor chips 200 and each of the plurality of second semiconductor chips 300 may be positioned on the same plane. The plurality of first semiconductor chips 200 and the plurality of second semiconductor chips 300 may form a lower chip stack LA.

In example embodiments, the first double die chip 400 may include a first double die substrate 410 having a front surface 412 and a backside surface 414 facing one another, and a plurality of third chip pads 420a, 420b exposed from the front surface 412 of the first double die substrate 410, a plurality of first redistribution wirings 425 connecting the plurality of third chip pads 420a and 420b, a third die attach film 430 provided on the backside surface 414 of the first double die substrate 410, and a plurality of third conductive connection members 440. For example, the front surface may be an active surface and the backside surface may be an inactive surface.

Further, the first double die chip 400 may include a passivation layer PL and an insulation layer IL that are sequentially stacked on the front surface 412 of the first double die substrate 410 to expose the plurality of third chip pads 420a, 420b. The insulation layers may include a first sub-insulation layer SIL1 and a second sub-insulation layer SIL2 that are sequentially stacked on the passivation layer PL. The first sub-insulation layer SIL1 may expose the plurality of third chip pads 420a, 420b, and the second sub-insulation layer SIL2 may expose portions of the plurality of first redistribution wirings 425. For example, the first double die chip may be a semiconductor chip including a scribe lane region and a pair of single die chips connected by the scribe lane region. The double die chip may be a semiconductor chip that has a scribe lane region between the pair of single die chips such that the pair of single die chips are connected to prevent collisions between semiconductor chips which are separated.

The first double die chip 400 may be stacked on the plurality of first semiconductor chips 200 and the plurality of second semiconductor chips 300. For example, the first double die chip 400 may include a first sub chip 400a adjacent to a first side portion S41, a second sub chip 400b adjacent to a second side portion S42, and a first connection portion 405 connecting the first sub chip 400a and the second sub chip 400b.

The first sub chip 400a may be stacked on the plurality of first semiconductor chips 200 via the third die attach film 430, and the second sub chip 400b may be stacked on the plurality of second semiconductor chips 300 via the third die attach film 430. For example, the first double die chip 400 may be stacked on the plurality of first semiconductor chips 200 such that the first sub chip 400a has a third offset OF3 from an outermost side portion of the third single die chip 200c. Further, the first double die chip 400 may be stacked on the plurality of second semiconductor chips 300 such that the second sub chip 400b has a third offset OF3 from an outermost side portion of the sixth single die chip 300c. For example, the third offset may be in a range of 250 μm to 300 μm.

The plurality of third chip pads 420a and 420b may include a plurality of first sub chip pads 420a arranged along the first direction Y to be adjacent to the first side portion S41 and a plurality of second sub chip pads 420b arranged along the first direction Y to be adjacent to the first connection portion 405. For example, the plurality of first sub chip pads 420a may be exposed from a front surface 412a of the first sub chip 400a, and the plurality of second sub chip pads 420b may be exposed from a front surface 412b of the second sub chip 400b. For example, the front surface may be an active surface on which electronic devices, such as transistors, are formed.

The plurality of first redistribution wirings 425 may be arranged in the second direction (Y direction) and may electrically connect each of the plurality of first sub chip pads 420a and each of the plurality of second sub chip pads 420b. Each of the plurality of first redistribution wirings 425 may extends in the first direction (X direction) to connect each of the plurality of first sub chip pads 420a and each of the plurality of second sub chip pads 420b. For example, the plurality of first redistribution wirings may include a conductive metallic material.

The plurality of third conductive connection members 440 may electrically connect the plurality of first redistribution wirings 425 and the plurality of first chip pads 220c. For example, the plurality of third conductive connection members may be a plurality of conductive wires.

In example embodiments, each of the plurality of third semiconductor chips 500 may include a plurality of fourth chip pads 520a, 520b and 520c, a plurality of fourth die attach films 530a, 530b and 530c, and a plurality of fourth conductive connection members 540. In addition, each of the plurality of third semiconductor chips 500 may have a front surface as an active surface 502a, 502b and 502c and a backside surface as an inactive surface 504a, 504b and 504c. For example, the plurality of third semiconductor chips may include non-volatile memory devices such as DRAM or NAND flash memory.

The plurality of third semiconductor chips 500 may be stacked sequentially on the front surface 402 of the first double die chip 400 to be adjacent to the first side portion S41 of the first double die chip 400. For example, the plurality of third semiconductor chips 500 may be stacked on the first sub chip 400a of the first double die chip 400. The plurality of third semiconductor chips 500 may be stacked on a portion 402a of the front side 402 of the first double die chip 400 via the fourth die attach film 530a, 530b and 530c provided on the backside surface 504a, 504b and 504c.

Each of the plurality of third semiconductor chips 500 may be sequentially offset aligned such that the plurality of fourth chip pads 520a, 520b and 520c, which is provided on the front surface 502a, 502b and 502c, are exposed. For example, the plurality of fourth semiconductor chips 400 may be stacked in a cascade structure.

For example, the plurality of third semiconductor chips 500 may include seventh to ninth single die chips 500a, 500b, 500c. The seventh single die chip 500a as a lowermost chip may be stacked on the first sub chip 400a of the first double die chip 400. The eighth single die chip 500b may be stacked on the seventh single die chip 500a to have a fourth offset OF4 from an outermost side portion of the seventh single die chip 500a. The ninth single die chip 500c may be stacked on the eighth single die chip 500b to have the fourth offset OF4 from an outermost side portion of the eighth single die chip 500b. For example, the fourth offset may be in a range of 250 μm to 300 μm.

The seventh single die chip 500a may include a seventh single die substrate 510a having a front surface 512a and a backside surface 514a facing one another, a plurality of chip pads 520a exposed from the front surface 512a, a first adhesive film 530a provided on the backside surface 514a, and a plurality of conductive connection members 540 connected to the plurality of chip pads 520a. The seventh single die chip 500a may have a first side portion S51 and a second side portion S52 extending in the second direction (Y direction) to face one another. The plurality of chip pads 520a may be arranged along the second side portion S52 to be adjacent to the second side portion S52. Further, the seventh single die chip 500a may include a passivation layer PL and a front insulation layer IL that are sequentially stacked on the front surface 512a to expose the plurality of chip pads 520a.

Although not illustrated in figures, the eighth single die chip 500b and the ninth single die chip 500c may be substantially identical to the seventh single die chip 500a. Accordingly, detail descriptions on the eighth single die chip 500b and the ninth single die chip 500c are omitted. Further, while the figures illustrate that the plurality of third semiconductor chips 500 includes three single die chips, the present inventive concept is not limited thereto. Accordingly, the number of the plurality of third semiconductor chips 500 may be varied.

The plurality of fourth conductive connection members 540 may electrically connect the plurality of fourth chip pads 520a, 520b, 520c to a portion of the plurality of third chip pads 420a and 420b, respectively. For example, the plurality of fourth conductive connection members may include a plurality of conductive wires.

In example embodiments, each of the plurality of fourth semiconductor chips 600 may include a plurality of fifth chip pads 620a, 620b and 620c, a fifth die attach film 630a, 630b and 630c, and a plurality of fifth conductive connection members 640. In addition, each of the plurality of fourth semiconductor chips 600 may have a front surface as an active surface 602a, 602b and 602c and a backside surface as an inactive surface 604a, 604b and 604c. For example, the plurality of fourth semiconductor chips may include non-volatile memory devices such as DRAM or NAND flash memory.

The plurality of fourth semiconductor chips 600 may be stacked sequentially on the front surface 402 of the first double die chip 400 to be adjacent to the second side portion S42 of the first double die chip 400. For example, the plurality of fourth semiconductor chips 600 may be stacked on the second sub chip 400b of the first double die chip 400. The plurality of fourth semiconductor chips 600 may be stacked on a portion 402b of the front surface 402 of the second double die chip 400 via the fifth die attach film 630a, 630b and 630c which is provided on the backside surface 604a, 604b and 604c.

Each of the plurality of fourth semiconductor chips 600 may be sequentially offset aligned such that the plurality of fifth chip pads 620a, 620b and 620c, which is provided on the front surfaces 602a, 602b and 602c, are exposed. For example, the plurality of fourth semiconductor chips 600 may be stacked in a cascade structure.

For example, the plurality of fourth semiconductor chips 600 may include tenth to twelfth single die chips 600a, 600b and 600c. The tenth single die chip 600a as a lowermost chip may be stacked on the second sub chip 400b of the first double die chip 400. The eleventh single die chip 600b may be stacked on the tenth single die chip 600a to have a fifth offset OF5 from an outermost side portion of the tenth single die chip 400a. The twelfth single die chip 600c may be stacked on the eleventh single die chip 600b to have the fifth offset OF5 from an outermost side portion of the eleventh single die chip 600b. For example, the fifth offset may be within a range of 250 μm to 300 μm.

Although not illustrated in figures, the tenth to twelfth single die chips 600a, 600b, 600c may be substantially identical to the seventh single die chip 500a. Accordingly, detail descriptions on the tenth to twelfth single die chips 600a, 600b and 600c will be omitted. Further, while the figures illustrate that the plurality of fourth semiconductor chips 600 includes three single die chips, the present inventive concept is not limited thereto. Accordingly, the number of the plurality of fourth semiconductor chips 600 may be varied.

The plurality of fifth conductive connection members 640 may electrically connect the plurality of fifth chip pads 620a, 620b and 620c and the plurality of second upper substrate pads 134, respectively. For example, the plurality of fifth conductive connection members may include a plurality of conductive wires.

For example, upper surface of each of the plurality of third semiconductor chips 500 and each of the plurality of fourth semiconductor chips 600 may be positioned on the same plane. The plurality of third semiconductor chips 500 and the plurality of fourth semiconductor chips 600 may form an upper chip stack UA.

In example embodiments, the second double die chip 700 may include a second double die substrate 710 having a front surface 712 and a backside surface 714 to face one another, and a plurality of sixth chip pads 720a and 720b exposed from the front surface 712 of the second double die substrate 710, a plurality of second redistribution wirings 725 connecting a portion of the plurality of sixth chip pads 720a and 720b, a sixth die attach film 730 provided on the backside surface 714 of the second double die substrate 710, and a plurality of sixth conductive connection members 740. For example, the front surface may be an active surface, and the backside surface may be an inactive surface.

The second double die chip 700 may also include a passivation layer PL and an insulation layer IL that are sequentially stacked on the front surface 712 of the second double die substrate 710 to expose the plurality of sixth chip pads 720a and 720b. The insulation layers may include a first sub insulation layer SIL1 and a second sub insulation layer SIL2 sequentially stacked on the passivation layer PL The first sub insulation layer SIL1 may expose the plurality of sixth chip pads 720a and 720b, and the second sub insulation layer SIL2 exposes portions of the plurality of second redistribution wirings 725. For example, the second double die chip may be a semiconductor chip including a scribe lane region and a pair of single die chips, and the pair of single die chips may be connected by the scribe lane region. The double die chip may be a semiconductor chip that includes the scribe lane region between the pair of single die chips such that the pair of single die chips are connected to prevent collisions between semiconductor chips which are separated.

The second double die chip 700 may be stacked on the plurality of third semiconductor chips 500 and the plurality of fourth semiconductor chips 600. For example, the second double die chip 700 may include a third sub chip 700a adjacent to the second side portion S72, a fourth sub chip 700b adjacent to the first side portion S71, and a second connection portion 705 connecting the third sub chip 700a and the fourth sub chip 700b.

The third sub chip 700a may be stacked on the plurality of fourth semiconductor chips 600 via the sixth die attach film 730, and the fourth sub chip 700b may be stacked on the plurality of third semiconductor chips 500 via the sixth die attach film 730. For example, the second double die chip 700 may be stacked on the plurality of third semiconductor chips 500 and the plurality of fourth semiconductor chips 600 such that the third sub chip 700a has a sixth offset OF6 from an outermost side portion of the twelfth single die chip 600c. For example, the sixth offset may be within a range of 250 μm to 300 μm.

The plurality of sixth chip pads 720a and 720b may include a plurality of third sub chip pads 720a arranged along the second direction Y adjacent to the first side portion S71 and a plurality of fourth sub chip pads 720b arranged along the first direction Y adjacent to the second connection portion 705. For example, the plurality of third sub chip pads 720a may be exposed from the front surface 712a of the third sub chip 700a, and the plurality of fourth sub chip pads 720b may be exposed from the front surface 712b of the fourth sub chip 700b. For example, the front surface may be an active surface on which electronic elements, such as transistors, are formed.

The plurality of second redistribution wirings 725 may be arranged in the second direction (Y direction) and may electrically connect the plurality of third sub chip pads 720a and the plurality of fourth sub chip pads 720b, respectively. Each of the plurality of second redistribution wirings 725 may extend in the first direction (X direction) to connect each of the plurality of third sub chip pads 720a and each of the plurality of fourth sub chip pads 720b. For example, the plurality of second redistribution wirings may include a conductive metallic material.

The plurality of sixth conductive connection members 740 may electrically connect the plurality of second redistribution wirings 725 and the plurality of fifth chip pads 620c. For example, the plurality of sixth conductive connection members may include a plurality of conductive wires.

For example, the first die attach film 230, the second die attach film 330, and the third die attach film 430 may have a first thickness T1. The sixth die attach film 730 may have a second thickness T2 greater than the first thickness T1. Thus, portions of the plurality of fourth conductive connection members 540 as bonding wires may be covered by the sixth die attach film 730.

Further, the fourth die attach film 530 may include a first adhesive film 530a provided under the seventh single die chip 500a, a second adhesive film 530b provided under the eighth single die chip 500b, and a third adhesive film 530c provided under the ninth single die chip 500c. The fifth die attach film 630 may include a fourth adhesive film 630a provided under the tenth single die chip 600a, a fifth adhesive film 630b provided under the eleventh single die chip 600b, and a sixth adhesive film 630c provided under the twelfth single die chip 600c.

The first adhesive film 530a and the fourth adhesive film 630a may have the second thickness T2, and the second adhesive film 530b, the third adhesive film 530c, the fifth adhesive film 630b, and the sixth adhesive film 630c may have the first thickness T1. Thus, portions of the plurality of third conductive connection members 440 as bonding wires may be covered by the first adhesive film 530a.

For example, the package substrate 100 may have a stacking region L from an outermost side portion of the first single die chip 200a to an outermost side portion of the fourth single die chip 300a. The plurality of first semiconductor chips 200, the plurality of second semiconductor chips 300, the first double die chip 400, the plurality of third semiconductor chips 500, the plurality of fourth semiconductor chips 600, and the second double die chip 700 may be provided within the stacking region. Thus, the size of the semiconductor package may be minimized.

For example, the plurality of first conductive connection members 240, the plurality of third conductive connection members 440, and the plurality of fourth conductive connection members 540 may be electrically connected to the plurality of first upper substrate pads 132 of the package substrate 100. The plurality of first conductive connection members 240, the plurality of third conductive connection members 440, and the plurality of fourth conductive connection members 540 may be a plurality of first channel connection members CA1. Additionally, the plurality of second conductive connection members 340, the plurality of fifth conductive connection members 640, and the plurality of sixth conductive connection members 740 may be electrically connected to the plurality of second upper substrate pads 134 of the package substrate 100. The plurality of second conductive connection members 340, the plurality of fifth conductive connection members 640, and the plurality of sixth conductive connection members 740 may be a plurality of second channel connection members CA2. The number of semiconductor chips which are electrically connected to the plurality of first upper substrate pads 132 may be equal to the number of semiconductor chips which are electrically connected to the plurality of second upper substrate pads 134. Thus, the semiconductor package 10 may be electrically symmetrical.

In example embodiments, the molding member 800 may be provided on the first surface 102 of the package substrate 100 to cover the plurality of first semiconductor chips 200, the plurality of second semiconductor chips 300, the first double die chip 400, the plurality of third semiconductor chips 500, the plurality of fourth semiconductor chips 600, and the second double die chip 700. For example, the molding member may include an epoxy molding compound (EMC).

In example embodiments, the plurality of external connection members 900 may be provided on the plurality of second substrate pads 150, which may be disposed on the second surface 104 of the package substrate 100. For example, the plurality of external connection members may include a conductive metallic material for electrically connecting the semiconductor package to an external device, such as a printed circuit board (PCB).

As described above, the semiconductor package 10 may include the package substrate 100, the plurality of first semiconductor chips 200 stacked on the package substrate 100 to be adjacent to the first side portion S1 of the package substrate 100, the plurality of second semiconductor chips 300 stacked on the package substrate 100 to be adjacent to the second side portion S2 of the package substrate 100, the first double die chip 400 stacked on the plurality of first semiconductor chips 200 and the plurality of second semiconductor chips 300, the plurality of third semiconductor chips 500 stacked on the first double die chip 400 to be adjacent to the first side portion S41 of the first double die chip 400, the plurality of fourth semiconductor chips 600 stacked on the first double die chip 400 to be adjacent to the second side portion S42 of the first double die chip 400, and the second double die chip 700 stacked on the plurality of third semiconductor chips 500 and the plurality of fourth semiconductor chips 600.

The first double die chip 400 may include the first sub chip 400a, the second sub chip 400b, and the first connection portion 415 connecting the first sub chip 400a and the second sub chip 400b. The second double die chip 700 may include the third sub chip 700a, the fourth sub chip 700b, and the second connection portion 705 connecting the third sub chip 700a and the fourth sub chip 700b.

Accordingly, the semiconductor package may prevent the semiconductor chips from cracking due to collision of semiconductor chips which are adjacently stacked.

Additionally, the plurality of first semiconductor chips 200 and the plurality of second semiconductor chips 300 may be stacked on the package substrate 100 with an offset such that the plurality of first semiconductor chips 200 and the plurality of second semiconductor chips 300 are close to a center portion of the package substrate 100. The package substrate 100 may include the stacking region L located between the outermost side portion of the plurality of first semiconductor chips 200 and the outermost side portion of the plurality of second semiconductor chips 300. The first double die chip 400, the second double die chip 700, the plurality of third semiconductor chips 500, and the plurality of fourth semiconductor chips 600 may be stacked in the stacking region L.

Accordingly, the size of the semiconductor package may be minimized.

Further, the package substrate 100 may have the plurality of first upper substrate pads 132 as first channels adjacent to the first side portion S1 and the plurality of second upper substrate pads 134 as second channels adjacent to the second side portion S2. The plurality of first upper substrate pads 132 may be electrically connected to the plurality of first semiconductor chips 200, the first double die chip 400, and the plurality of third semiconductor chips 500. The plurality of second upper substrate pads 134 can be electrically connected to the plurality of second semiconductor chips 300, the plurality of third semiconductor chips 500, and the second double die chip 700. Further, the number of the plurality of first semiconductor chips 200 and the number of the plurality of second semiconductor chips 300 may be the same. The number of the plurality of third semiconductor chips 500 and the number of the plurality of fourth semiconductor chips 600 may be the same.

Accordingly, the semiconductor package may satisfy electrical symmetry. Accordingly, the semiconductor package may satisfy the joint electron device engineering council (JEDEC) standard.

Hereinafter, a method of manufacturing the semiconductor package 10 in FIG. 1 will be described.

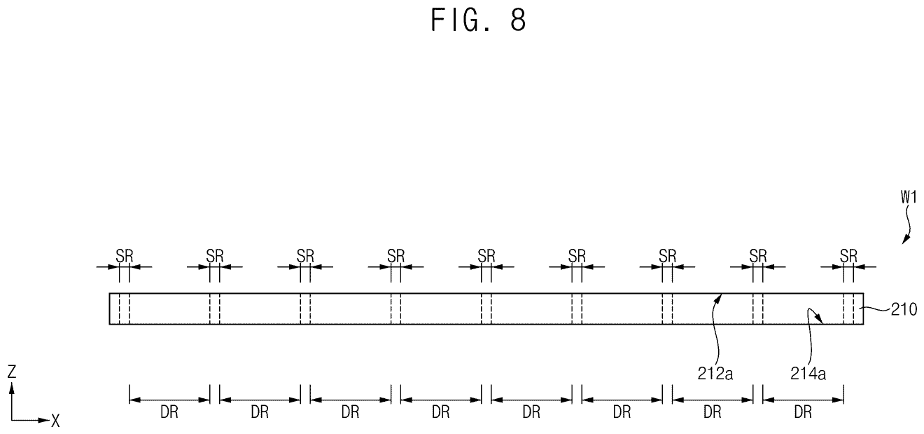

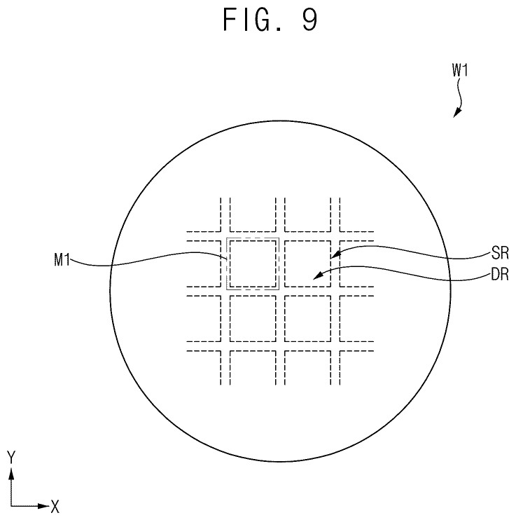

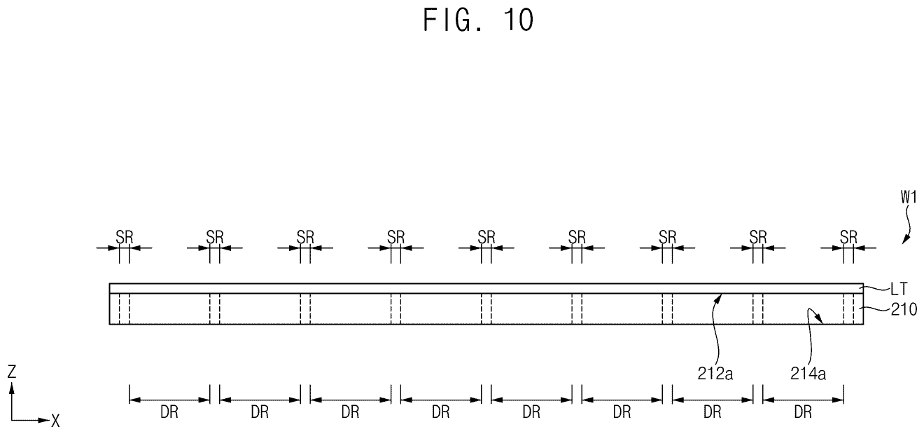

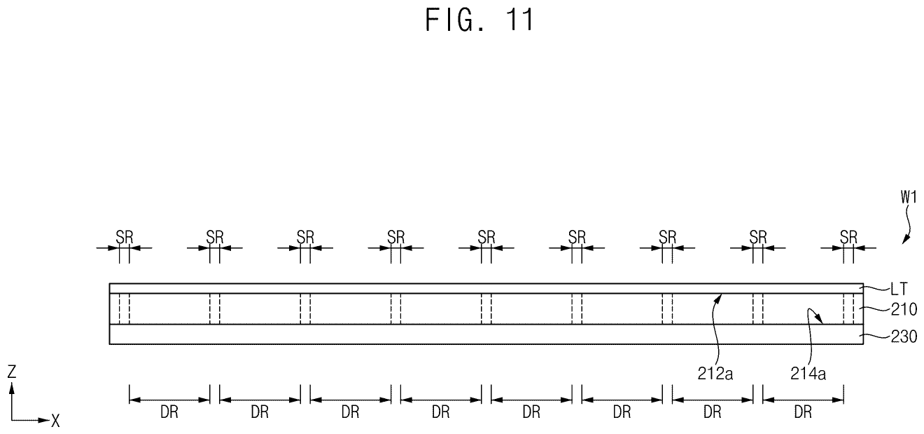

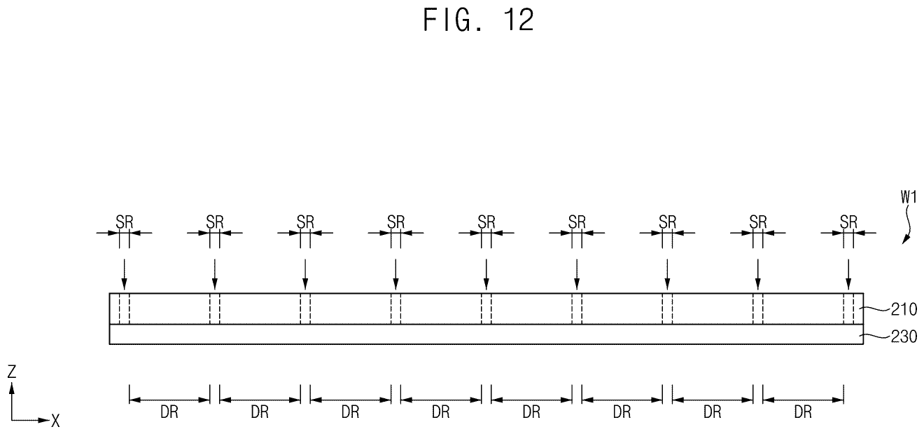

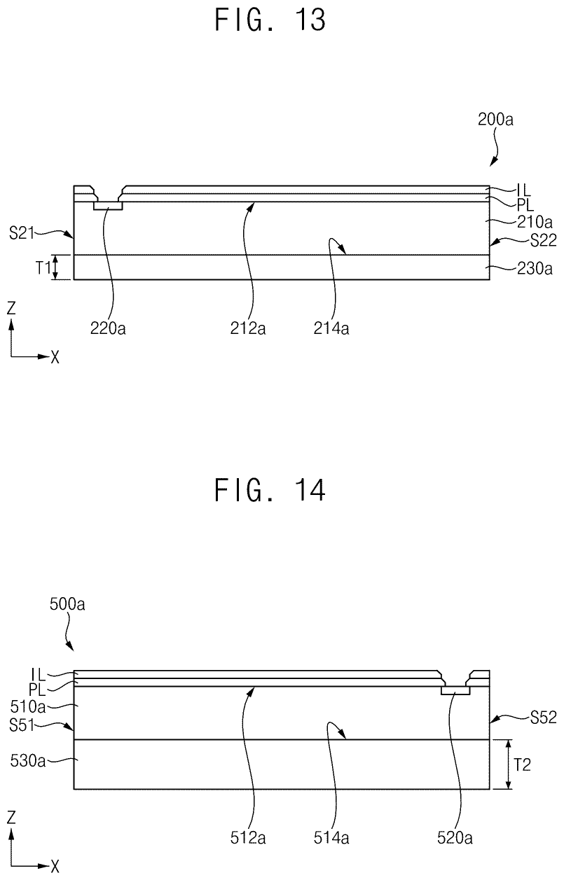

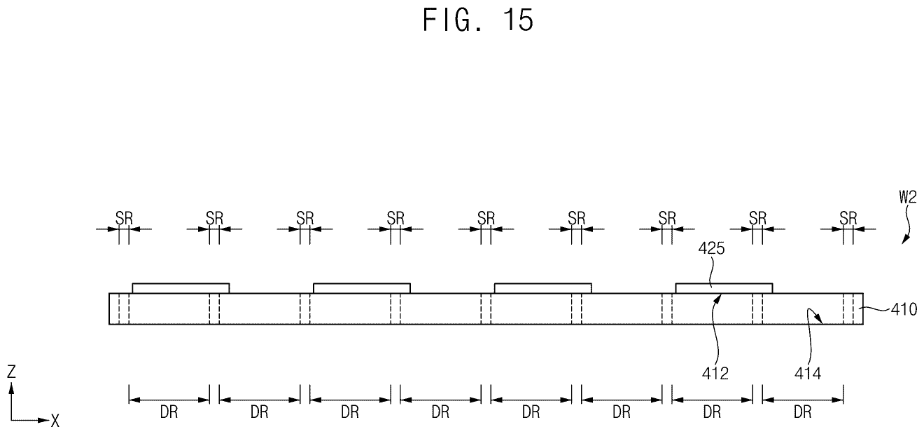

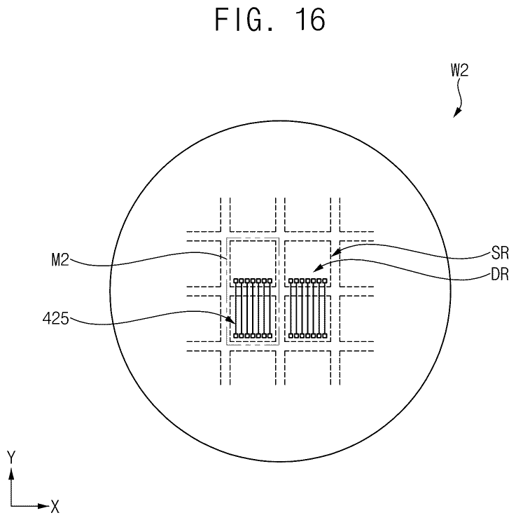

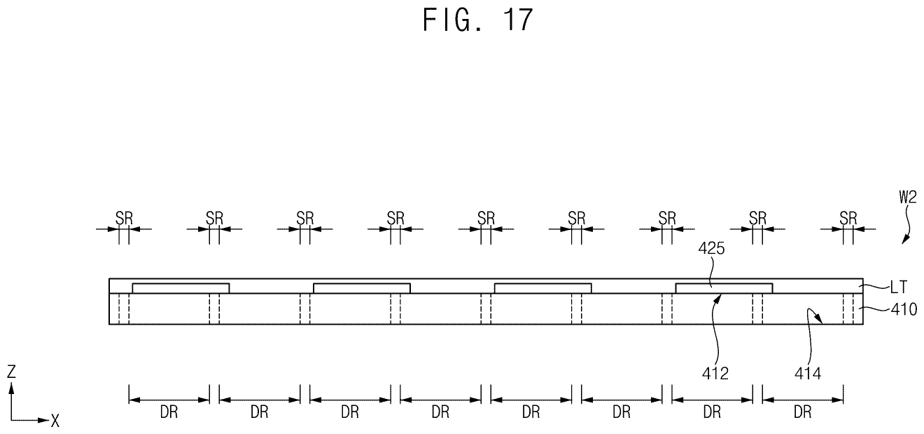

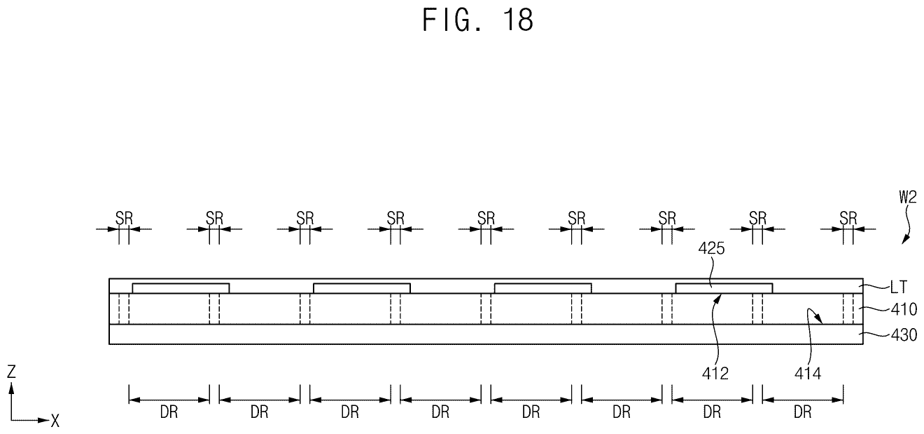

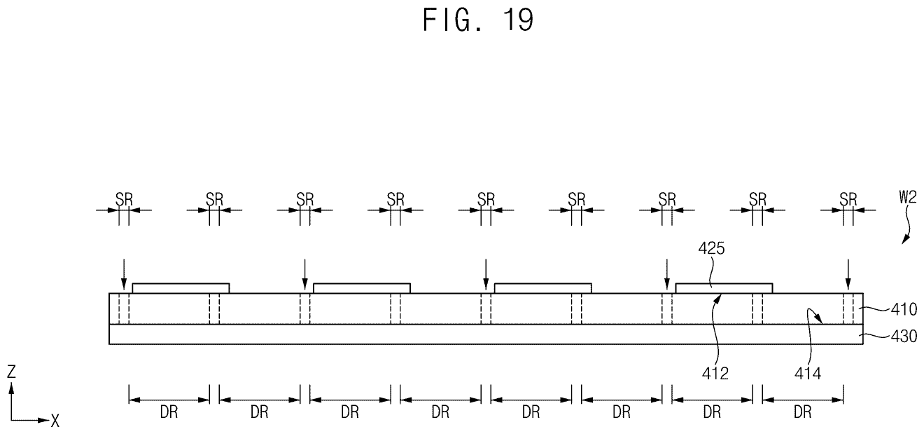

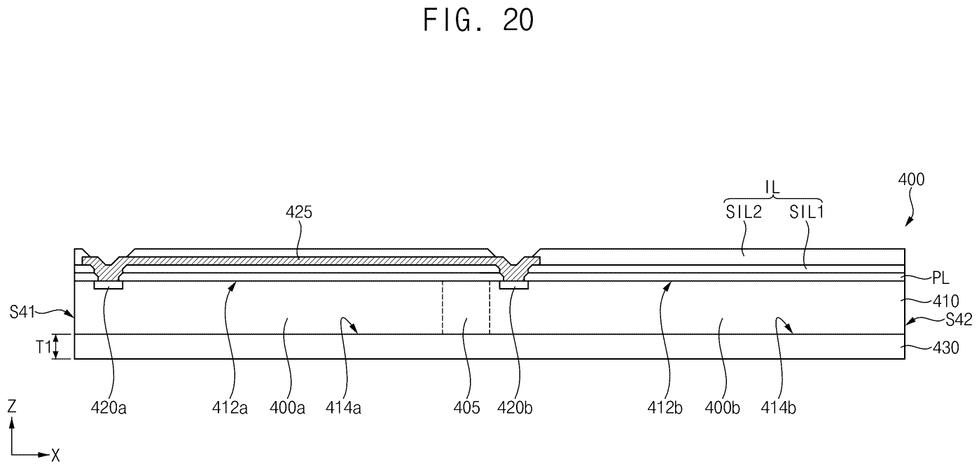

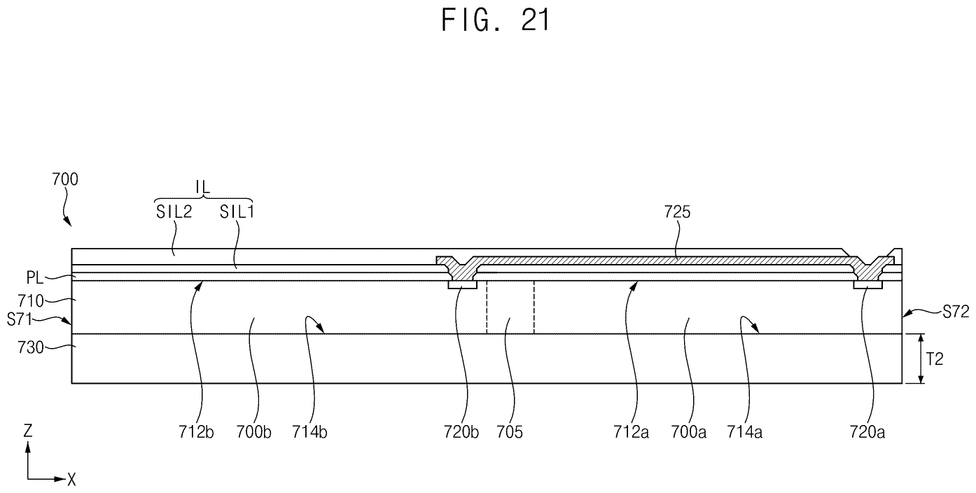

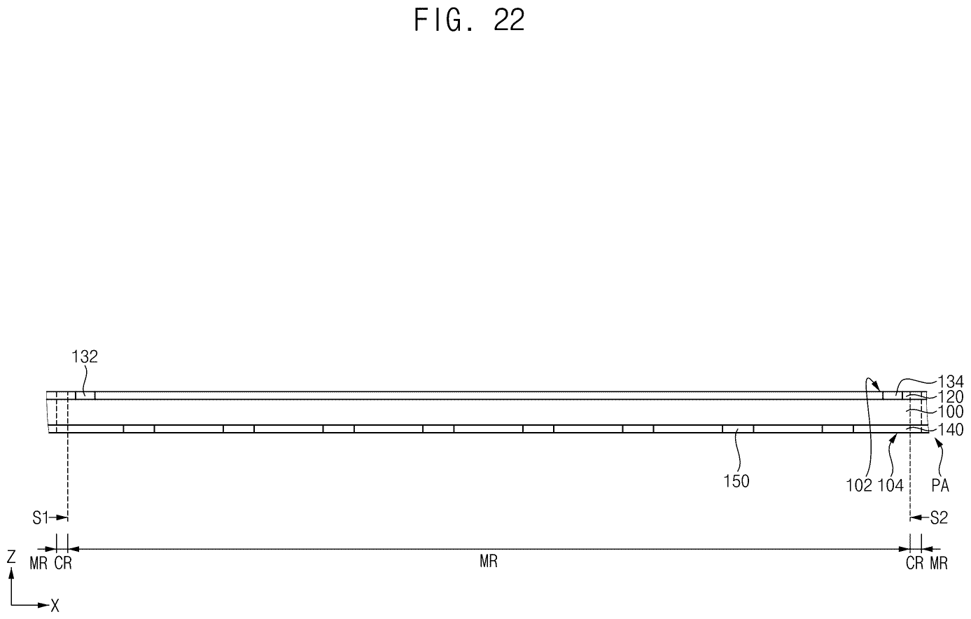

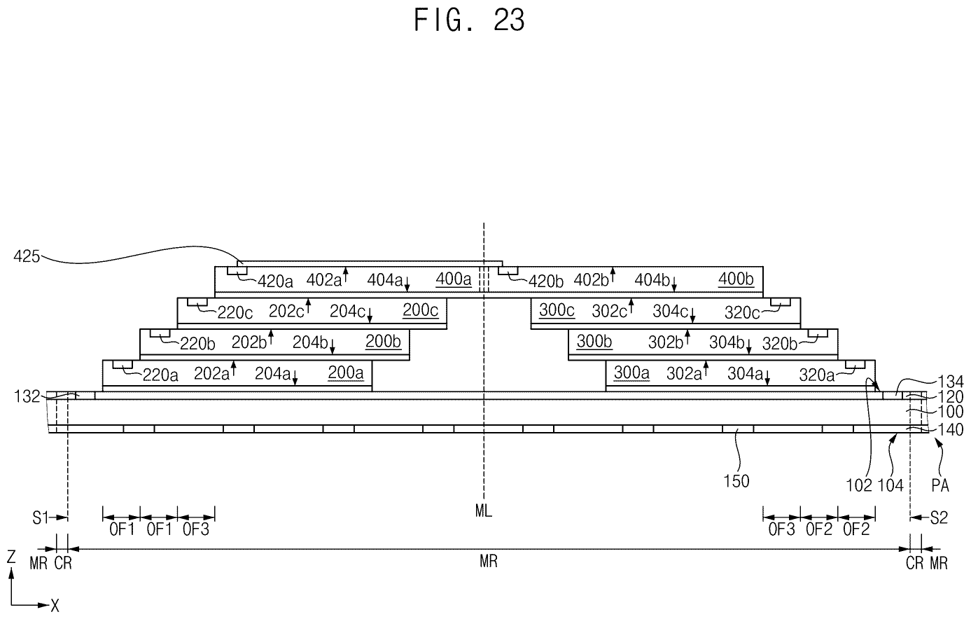

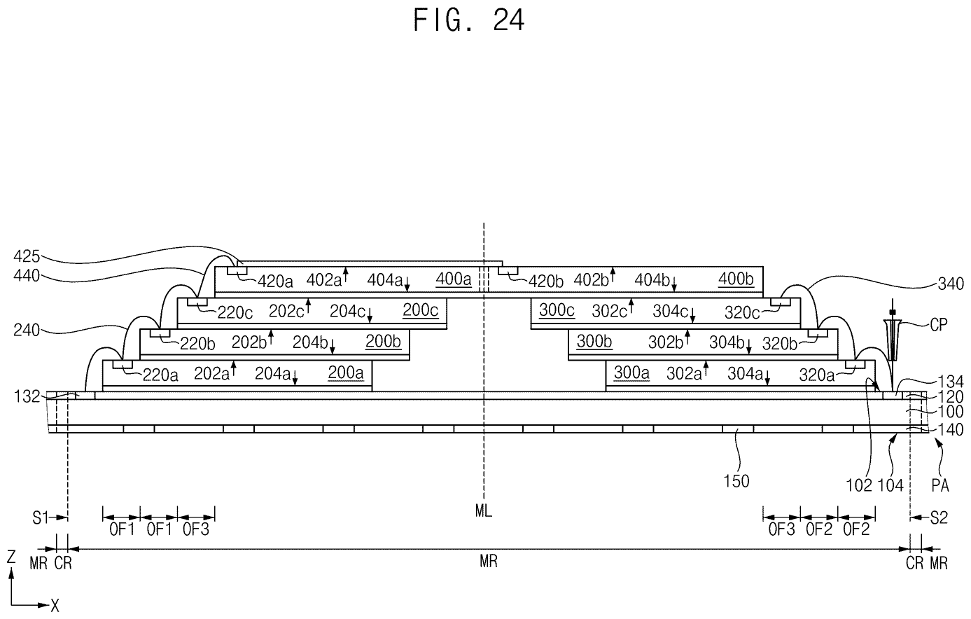

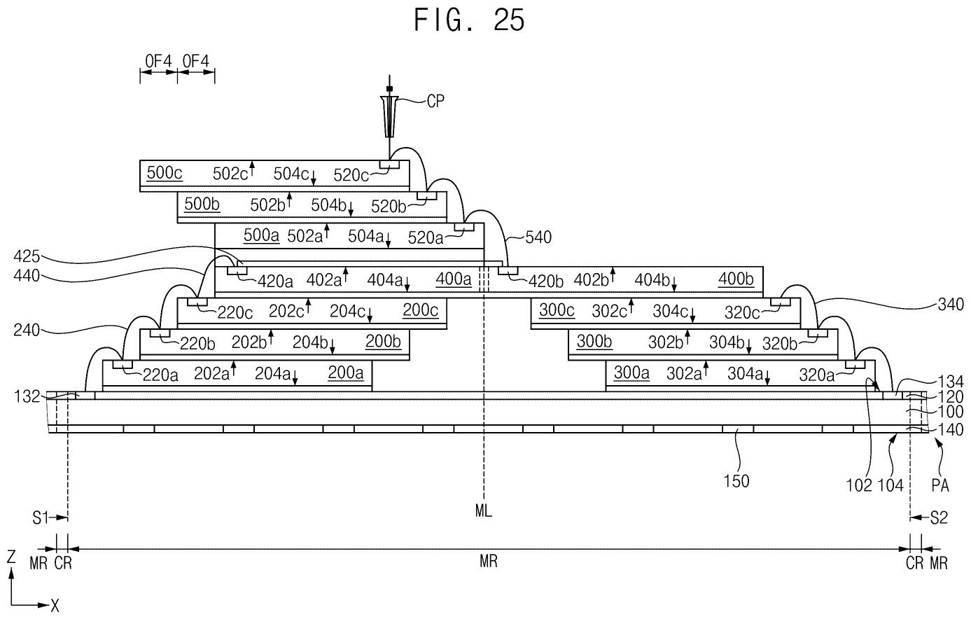

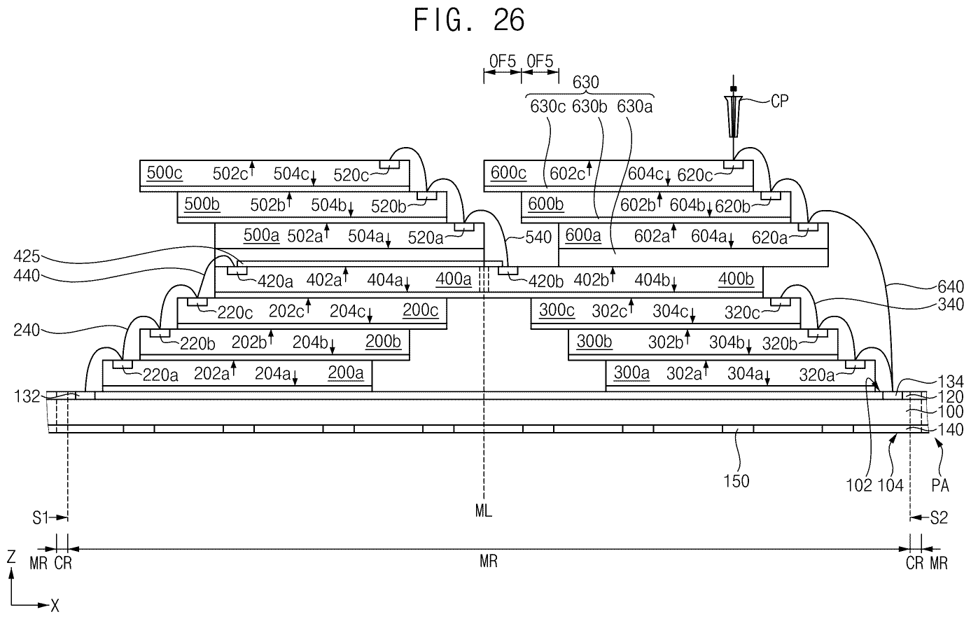

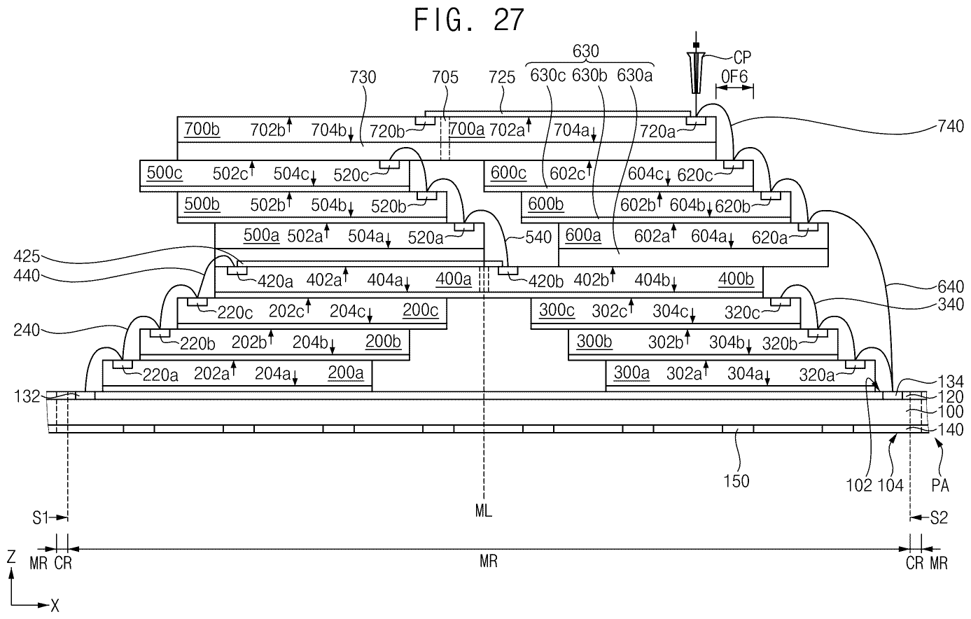

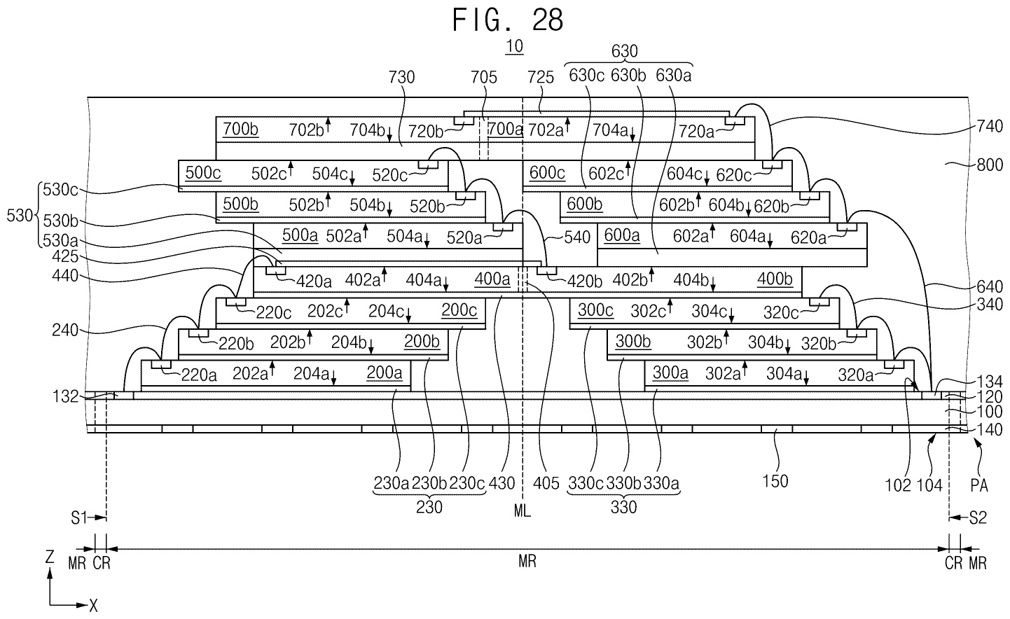

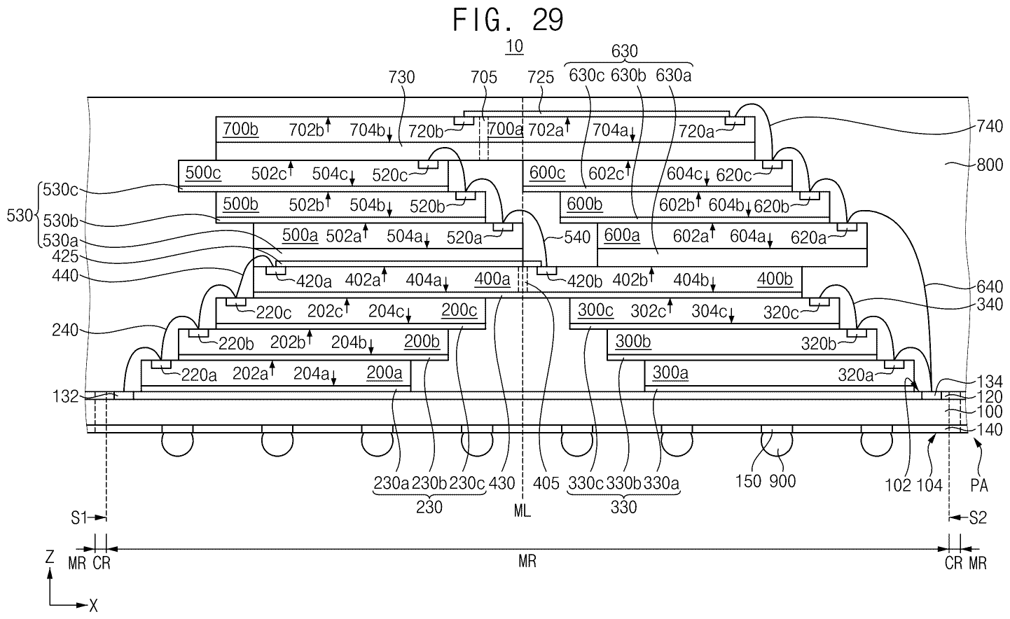

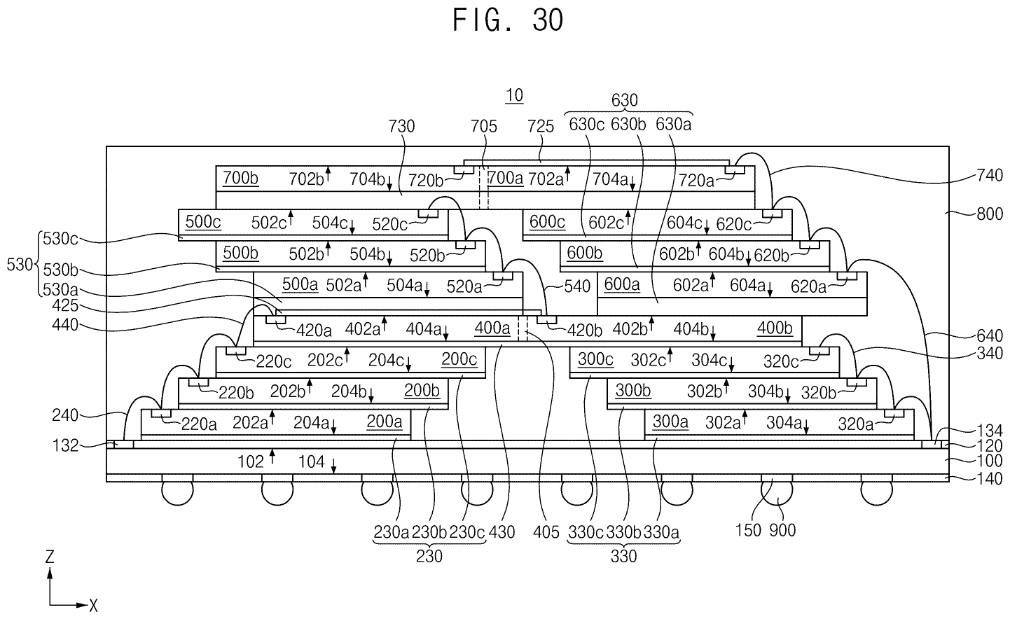

FIG. 8 is a cross-sectional view illustrating a first wafer in accordance with example embodiments. FIG. 9 is a plan view illustrating the first wafer in FIG. 8. FIG. 10 is a cross-sectional view illustrating attachment of a lamination tape to a front surface of the first wafer in FIG. 8. FIG. 11 is a cross-sectional view illustrating attachment of a die attach film to a backside surface of the first wafer in FIG. 10. FIGS. 12 and 13 are views illustrating a first single die chip formed by cutting the first wafer in FIG. 11. FIG. 14 is a cross-sectional view illustrating a seventh single die chip. FIG. 15 is a cross-sectional view illustrating a second wafer in accordance with example embodiments. FIG. 16 is a plan view illustrating the second wafer in FIG. 15. FIG. 17 is a cross-sectional view illustrating attachment of lamination tape to a front surface of the second wafer in FIG. 15. FIG. 18 is a cross-sectional view illustrating attachment of a die attach film to a backside surface of the first wafer in FIG. 15. FIGS. 19 and 20 are views illustrating a first double die chip formed by cutting the second wafer in FIG. 18. FIG. 21 is a cross-sectional view illustrating a second double die chip. FIG. 22 is a cross-sectional view illustrating a substrate array in accordance with example embodiments. FIG. 23 is a cross-sectional view illustrating stacking a plurality of first semiconductor chips and a plurality of second semiconductor chips on the substrate array in FIG. 22. FIG. 24 is a cross-sectional view illustrating forming a plurality of first conductive connection members and a plurality of second conductive connection members. FIG. 25 is a cross-sectional view illustrating stacking a plurality of third semiconductor chips and forming a plurality of third conductive connection members. FIG. 26 is a cross-sectional view illustrating stacking a plurality of fourth semiconductor chips and forming a plurality of fourth conductive connection members. FIG. 27 is a cross-sectional view illustrating stacking a second double die chip and forming a plurality of fifth conductive connection members. FIG. 28 is a cross-sectional view illustrating forming a molding member on a first surface of the substrate array. FIG. 29 is a cross-sectional view illustrating attaching a plurality of external connection members to a second surface of the substrate array. FIG. 30 is a cross-sectional view illustrating cutting along a cutting region of the substrate array to complete the semiconductor package in FIG. 1.

Since the semiconductor package manufactured by the manufacturing process illustrated in FIGS. 8 to 30 is substantially the same as the semiconductor package 10 described in FIGS. 1 to 7, identical components are denoted by the same reference numerals, and repeated descriptions of identical components are omitted.

Referring to FIGS. 8 and 9, a first wafer W1 may be provided including a plurality of die regions DR and a scribe lane region SR connecting the plurality of die regions DR. For example, the first wafer W1 may be individualized into a single die M1 by removing the scribe lane region SR through a singulation process to be described later. For example, the first wafer W1 may include a first single die substrate 210 having a front surface 212a and a backside surface 214a facing one another. For example, the front surface may be an active surface on which electronic elements, such as a transistor, etc., is formed, and the backside surface may be an inactive surface.

Referring to FIGS. 10 and 11, a lamination tape LT may be attached to the front surface 212a of the first wafer W1, and a first die attach film 230 may be attached to the backside surface 214a of the first wafer W1. For example, the lamination tape may be a structure configured to protect electronic elements formed on the front surface 212a of the first wafer W1. Further, the die attach film may be an adhesive film configured to attach individualized semiconductor chips to a package substrate and semiconductor chips by a singulation process to be described later. The die attach film may have a first thickness T1.

Referring to FIGS. 12 and 13, the lamination tape LT may be removed from the first wafer W1, and a singulation process may be performed along the scribe lane region SR, thereby providing the first single die chip 200a. For example, the singulation process may be a blade dicing process, in which the scribe lane region SR is removed by a blade, or a laser dicing process, in which microscopic cracks are formed by a laser along the scribe lane region SR and then an external force is applied to individualize the plurality of dies.

Although not illustrated in figures, the second to sixth single die chips 200b, 200c, 300a, 300b and 300c, the eighth single die chip 500b, the ninth single die chip 500c, the eleventh single die chip 600b, and the twelfth single die chip 600c may be manufactured by using substantially the same method as the first single die chip 200a.

Referring to FIG. 14, a seventh single die chip 500a may be provided, wherein the seventh single die chip 500a has a first adhesive film 530a having a second thickness T2. For example, the second thickness may be greater than the first thickness.

The seventh single die chip 500a may be manufactured by using substantially the same methods as the fabrication methods illustrated in FIGS. 8 to 13 except for the thickness of the die attach film that is attached to the backside surface of the wafer.

Although not illustrated in figures, the tenth single die chip 600a may be manufactured by using substantially the same method as the seventh single die chip 500a.

Referring to FIGS. 15 and 16, a second wafer W2 may be provided, the second wafer providing a plurality of die regions DR and a scribe lane region SR connecting the plurality of die regions DR. The second wafer W2 may include a plurality of first redistribution wirings 425 electrically connecting each of a pair of chip pads provided on adjacent die regions.

For example, a portion of the scribe lane regions SR may be removed by a singulation process to be described later to individualize the second wafer W2 as a double die M2. For example, the second wafer W2 may include a first double die substrate 410 having a front surface 412a and a backside surface 414a facing one another. For example, the front surface may be an active side, on which electronic elements such as transistors are formed, and the backside surface may be an inactive side.

Referring to FIGS. 17 and 18, a lamination tape LT may be attached to the front surface 412 of the second wafer W2, and a third die attach film 430 may be attached to the backside surface 414 of the second wafer W2. For example, the lamination tape may be a structure configured to protect electronic devices and a plurality of first redistribution wirings 425 formed on the front surface 412 of the second wafer W2. Further, the die attach film may be an adhesive film configured to attach the semiconductor chips, which are individualized by a singulation process to be described later, to the package substrate and the semiconductor chips. The die attach film may have a first thickness T1.

Referring to FIGS. 19 and 20, the lamination tape LT may be removed from the second wafer W2, and a singulation process may be performed along a portion of the scribe lane region SR, thereby providing the first double die chip 400. For example, the singulation process may be a blade dicing process, in which a blade is used to remove the scribe lane region SR, or a laser dicing process, in which microscopic cracks are formed along the scribe lane region SR by a laser and then an external force is applied to individualize the plurality of dies.

Referring to FIG. 21, a second double die chip 700 may be provided. The second double die chip 700 may include a sixth die attach film 730 having a second thickness T2.

The second double die chip 700 may be manufactured by using substantially the same method as the method illustrated in FIGS. 15 to 2, except for the thickness of the die attach film that is attached to the backside surface of the wafer.

Referring to FIG. 22, a package array PA may be provided, the package array having a plurality of mounting regions MR and a cutting region CR connecting the plurality of mounting regions MR.

Referring to FIG. 23, a plurality of first semiconductor chips 200 and a plurality of second semiconductor chips 300 may be stacked on the mounting region of the package array PA. Subsequently, a first double die chip 400 may be stacked on the plurality of first semiconductor chips 200 and the plurality of second semiconductor chips 300.

First, the plurality of first semiconductor chips 200 may be sequentially attached via the first die attach film 230 to be adjacent to the first side portion S1 of the mounting region. For example, a first single die chip 200a may be attached to the mounting region, a second single die chip 200b may be attached to the first single die chip 200a such that the first single die chip 200a has a first offset OF1 from an outermost side portion of the first single die chip 200a, and a third single die chip 200c may be attached to the second single die chip 200b such that the third single die chip 200c has the first offset OF1 from an outermost side of the second single die chip 200b.

Thereafter, the plurality of second semiconductor chips 300 may be sequentially attached via the second die attach film 330 to be to the second side portion S2 of the mounting region such that the plurality of second semiconductor chips 300 are symmetrical with the plurality of first semiconductor chips 200 with respect to the centerline ML of the mounting region. For example, a fourth single die chip 300a may be attached to the mounting region, a fifth single die chip 300b may be attached to the fourth single die chip 300a such that the fifth single die chip 300b has a second offset OF2 from an outermost side portion of the fourth single die chip 300a, and a sixth single die chip 300c may be attached to the fifth single die chip 300b such that the sixth single die chip 300c has the second offset OF2 from an outermost side portion of the fifth single die chip 300b. For example, a length of the first offset may be equal to a length of the second offset.

Thereafter, the first double die chip 400 may be attached such that the first sub chip 400a of the first double die chip 400 is located on the plurality of first semiconductor chips 200 and such that the second sub chip 400b of the first double die chip 400 is located on the plurality of second semiconductor chips 300. For example, the third die attach film 430 may be utilized to attach the backside surface 404a of the first sub chip 400a and the front surface 202c of the third single die chip 200c. Additionally, the third die attach film 430 may be utilized to attach the backside surface 402b of the second sub chip 400b and the front surface 302c of the sixth single die chip 300c.

The first double die chip 400 may be stacked on the third single die chip 200c such that the first double die chip 400 has a third offset OF3 from an outermost side portion of the third single die chip 200c. Further, the first double die chip 400 may be stacked on the sixth single die chip 300c such that the first double die chip 400 has the third offset OF3 from an outermost side portion of the sixth single die chip 300c.

Referring to FIG. 24, by a wire bonding process, a plurality of first conductive connection members 240 may be formed, wherein the plurality of first conductive connection members 240 electrically connect the plurality of first semiconductor chips 200 and the plurality of first upper substrate pads 132, respectively, a plurality of second conductive connection members 340 may be formed, wherein the plurality of second conductive connection members 340 electrically connect the plurality of second semiconductor chips 300 and the plurality of second upper substrate pads 134, respectively, and a plurality of third conductive connection members 440 may be formed, wherein the plurality of third conductive connection members 440 electrically connect a portion 200c of the plurality of first semiconductor chips 200 and the first double die chip 400. For example, the wire bonding process may be performed in a thermersonic manner.

Referring to FIG. 25, a plurality of third semiconductor chips 500 may be sequentially attached to the first sub chip 400a of the first double die chip 400 via the fourth die attach film 530, and by a wire bonding process, a plurality of fourth conductive connection members 540 may be formed, wherein the plurality of fourth conductive connection members 540 electrically connect the plurality of third semiconductor chips 500 and the first double die chip 400, respectively. For example, the wire bonding process may be performed in a thermersonic manner.

For example, a seventh single die chip 500a may be attached to the first sub chip 400a, an eighth single die chip 500b may be attached to the seventh single die chip 500a such that the eighth single die chip 500b has a fourth offset OF4 from an outermost side portion of the seventh single die chip 500a, and a ninth single die chip 500c may be attached to the eighth single die chip 500b such that the ninth single die chip 500c has the fourth offset OF4 from an outermost side of the eighth single die chip 500b.

Referring to FIG. 26, a plurality of fourth semiconductor chips 600 may be sequentially attached to the second sub chip 400b of the first double die chip 400 via the fifth die attach film 630, and, by a wire bonding process, a plurality of fifth conductive connection members 640 may be formed, wherein the plurality of fifth conductive connection members 640 electrically connect the plurality of fourth semiconductor chips 600 and the plurality of second upper substrate pads 134, respectively. For example, the wire bonding process may be performed in a thermersonic manner.

For example, a tenth single die chip 600a may be attached to at least a portion of the second sub chip 400b, an eleventh single die chip 600b may be attached to the tenth single die chip 600a such that the eleventh single die chip 600b has a fifth offset OF5 from an outermost side portion of the tenth single die chip 600a, and a twelfth single die chip 600c may be attached to the eleventh single die chip 600b such that the twelfth single die chip 600c has the fifth offset OF5 from an outermost side portion of the eleventh single die chip 600b.

Referring to FIG. 27, the second double die chip 700 may be stacked on the plurality of third semiconductor chips 500 and the plurality of fourth semiconductor chips 600, and, by a wire bonding process, a plurality of sixth conductive connection members 740 may be formed, wherein the plurality of sixth conductive connection members 740 are electrically connected to a portion 600c of the plurality of fourth semiconductor chips 600, respectively. For example, the wire bonding process may be performed in a thermersonic manner.

Thereafter, the second double die chip 700 may be attached such that the fourth sub chip 700b of the second double die chip 700 is located on the plurality of third semiconductor chips 500 and such that the third sub chip 700a of the second double die chip 700 is located on the plurality of fourth semiconductor chips 600. For example, the backside 704a of the third sub chip 700a may be attached to the front surface 602c of the twelfth single die chip 600c via the sixth die attach film 730. Additionally, the backside 702b of the fourth sub chip 700b may be attached to the front surface 502c of the ninth single die chip 500c via the sixth die attach film 730.

The second double die chip 700 may be stacked on the twelfth single die chip 600c and the ninth single die chip 500c such that the second double die chip 700 has an offset OF6 from an outermost side portion of the twelfth single die chip 600c.

Referring to FIG. 28, a molding member 800 may be formed on the first surface 102 of the package substrate 100 to cover the plurality of first semiconductor chips 200, the plurality of second semiconductor chips 300, the first double die chip 400, the plurality of third semiconductor chips 500, the plurality of fourth semiconductor chips 600, and the second double die chip 700. For example, the molding member may include an epoxy molding compound (EMC).

Referring to FIG. 29, a plurality of external connection members 900 may be attached to the plurality of second substrate pads 150 of the package substrate 100. For example, the plurality of external connection members may include a conductive metallic material for electrically connecting the semiconductor package to an external device, such as a printed circuit board (PCB).

Referring to FIG. 30, a sawing process may be performed along the cutting region CR of the package array PA to complete the semiconductor package 10 in FIG. 1.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A semiconductor package, comprising:
a package substrate providing a first side portion and a second side portion extending in a first direction to face one another, the package substrate including a plurality of first substrate pads adjacent to the first side portion and a plurality of second substrate pads adjacent to the second side portion;
a first chip stack sequentially stacked on a first surface of the package substrate, wherein the first chip stack includes a plurality of first semiconductor chips electrically connected to the plurality of first substrate pads respectively by a plurality of first conductive connection members and adjacent to the first side portion of the package substrate and a plurality of second semiconductor chips electrically connected to the plurality of second substrate pads respectively by a plurality of second connection members and adjacent to the second side portion of the package substrate; and
a first double die chip provided on the first chip stack, wherein the first double die chip includes a first sub chip stacked on the plurality of first semiconductor chips electrically connected to the plurality of first semiconductor chips respectively by a plurality of third conductive connection members, a second sub chip stacked on the plurality of second semiconductor chips, and a first connection portion connecting the first sub chip to the second sub chip.

2. The semiconductor package of claim 1, further including a second chip stack sequentially stacked on the first double die chip, wherein the second chip stack includes a plurality of third semiconductor chips sequentially stacked on the first sub chip electrically connected to the second sub chip respectively by a plurality of fourth conductive connection members and a plurality of fourth semiconductor chips sequentially stacked on the second sub chip electrically connected to the plurality of second substrate pads by a plurality of fifth conductive connection members; and
a second double die chip provided on the second chip stack, wherein the second double die chip includes a third sub chip stacked on the plurality of fourth semiconductor chips electrically connected to the plurality of fourth semiconductor chips respectively by a plurality of sixth conductive connection members, a fourth sub chip stacked on the plurality of third semiconductor chips, and a second connection portion connecting the third sub chip to the fourth sub chip.

3. The semiconductor package of claim 2, wherein the first sub chip of the first double die chip includes a plurality of first sub chip pads arranged along the first direction and adjacent to a side portion of the first double die chip,
wherein the second sub chip of the first double die chip includes a plurality of second sub chip pads arranged along the first direction and adjacent to first connection portion,
wherein the third sub chip of the second double die chip includes a plurality of third sub chip pads arranged along the first direction and adjacent to a side portion of the second double die chip,
wherein the fourth sub chip of the second double die chip includes a plurality of fourth sub chip pads along the first direction and adjacent to the second connection portion; and
wherein the first double die chip includes a plurality of first redistribution wirings electrically connecting the plurality of first sub chip pads to the plurality of second sub chip pads and respectively extending a second direction perpendicular to the first direction.

4. The semiconductor package of claim 3, wherein the second double die chip includes a plurality of second redistribution wirings electrically connecting the plurality of third sub chip pads to the plurality of fourth sub chip pads and respectively extending a second direction perpendicular to the first direction.

5. The semiconductor package of claim 2, wherein a number of the plurality of first semiconductor chips is equal to a number of the plurality of second semiconductor chips, and
wherein a number of the plurality of third semiconductor chips is equal to a number of the plurality fourth semiconductor chips.

6. The semiconductor package of claim 1, wherein the plurality of first semiconductor chips and the plurality of second semiconductor chips are symmetrical to one another with respect to a center line of the package substrate.

7. The semiconductor package of claim 2, wherein the plurality of first semiconductor chips, the plurality of second semiconductor chips, the plurality of third semiconductor chips and the plurality of fourth semiconductor chips respectively have an offset to expose a plurality of chip pads in a direction opposite to the package substrate.

8. The semiconductor package of claim 1, wherein the first double die chip includes a first die attach film having a first thickness, and
wherein the second double die chip includes a second die attach film having a second thickness greater than the first thickness.

9. The semiconductor package of claim 2, further comprising:
a molding member provided on the first surface of the package substrate to cover the first chip stack, the first double die chip, the second chip stack, and the second double die chip.

10. The semiconductor package of claim 1, further comprising:
a plurality of third substrate pads provided on a second surface of the package substrate opposite to the first surface of the package substrate, and
a plurality of external connection members respectively provided on the plurality of third substrate pads.

11. A semiconductor package, comprising:
a package substrate providing a first surface and a second surface facing one another, the package substrate having a plurality of first substrate pads and a plurality of second substrate pads provided on the first surface to be symmetrical with one another with respect to a center line;
a lower chip stack including a plurality of first semiconductor chips adjacent to the plurality of first substrate pads and a plurality of second semiconductor chips adjacent to the plurality of second substrate pads, wherein the plurality of first semiconductor chips and the plurality of second semiconductor chips are sequentially stacked on the first surface of the package substrate to be symmetrical to one another with respect to the center line of the package substrate;
a first double die chip stacked on the lower chip stack, wherein the first double die chip includes a first sub chip stacked on the plurality of first semiconductor chips, a second sub chip stacked on the plurality of second semiconductor chips, and a first connection portion connecting the first sub chip to the second sub chip;
an upper chip stack provided on the first double die chip, wherein the upper chip stack includes a plurality of third semiconductor chips sequentially stacked on the first sub chip and a plurality of fourth semiconductor chips sequentially stacked on the second sub chip;
a second double die chip stacked on the upper chip stack, wherein the second double die chip includes a third sub chip stacked on the plurality of fourth semiconductor chips, a fourth sub chip stacked on the plurality of third semiconductor chips, and a second connection portion connecting the third sub chip to the fourth sub chip;
a plurality of first channel connection members electrically connecting the plurality of first substrate pads, the plurality of first semiconductor chips, the first double die chip and the plurality of third semiconductor chips; and
a plurality of second channel connection members electrically connecting the plurality of second substrate pads, the plurality of second semiconductor chips, the plurality of fourth semiconductor chips and the second double die chip.

12. The semiconductor package of claim 11, wherein the first sub chip of the first double die chip includes a plurality of first sub chip pads arranged along a first direction and adjacent to a side portion of the first double die chip, and
wherein the second sub chip of the first double die chip includes a plurality of second sub chip pads arranged along the first direction and adjacent to the first connection portion.

13. The semiconductor package of claim 12, wherein the first double die chip a plurality of first redistribution wirings electrically connecting the plurality of first sub chip pads to the plurality of second sub chip pads and respectively extending a second direction perpendicular to the first direction.

14. The semiconductor package of claim 11, wherein the third sub chip of the second double die chip includes a plurality of third sub chip pads arranged along a first direction and adjacent to a side portion of the second double die chip, and
wherein the fourth sub chip of the second double die chip includes a plurality of fourth sub chip pads along the first direction and adjacent to the second connection portion.

15. The semiconductor package of claim 14, wherein the second double die chip includes a plurality of second redistribution wirings electrically connecting the plurality of third sub chip pads to the plurality of fourth sub chip pads and respectively extending a second direction perpendicular to the first direction.

16. The semiconductor package of claim 11, wherein a number of the plurality of first semiconductor chips is equal to a number of the plurality of second semiconductor chips, and
wherein a number of the plurality of third semiconductor chips is equal to a number of the plurality of fourth semiconductor chips.

17. The semiconductor package of claim 16, wherein the plurality of first channel connection members includes,
a plurality of first conductive wires electrically connecting the plurality of first substrate pads to the plurality of first semiconductor chips;
a plurality of second conductive wires electrically connecting the plurality of first semiconductor chips to the first double die chip; and
a plurality of third conductive wires electrically connecting the plurality of first double die chip to the plurality of third semiconductor chips.

18. The semiconductor package of claim 16, wherein the plurality of second channel connection members includes,
a plurality of fourth conductive wires electrically connecting the plurality of second substrate pads to the plurality of second semiconductor chips;
a plurality of fifth conductive wires electrically connecting the plurality of second semiconductor chips to the fourth semiconductor chips; and
a plurality of sixth conductive wires electrically connecting the plurality of fourth semiconductor chips to the second double die chip.

19. The semiconductor package of claim 11, further comprising:
a molding member provided on the first surface of the package substrate to cover the lower chip stack, the first double die chip, the upper chip stack, the second double die chip, the plurality of first channel connection members, and the plurality of second channel connection members.

20. A semiconductor package, comprising:
a package substrate providing a first side portion and a second side portion extending ion a first direction to face one another, the package substrate having a plurality of first substrate pads adjacent to the first side portion and a plurality of second substrate pads adjacent to the second side portion;
a plurality of first semiconductor chips sequentially stacked on the package substrate to be adjacent to the first side portion of the package substrate and arranged to have an offset such that a first surface on which a plurality of first chip pads are formed faces upwardly;
a plurality of second semiconductor chips sequentially stacked on the package substrate to be adjacent to the second side portion of the package substrate and arranged to have an offset such that a first surface on which a plurality of second chip pads are formed faces upwardly;
a first double die chip including a first sub chip stacked on an uppermost first semiconductor chip among the plurality of first semiconductor chips such that a first surface on which a first sub chip pad is formed faces upwardly, a second sub chip stacked on an uppermost second semiconductor chip among the plurality of second semiconductor chips such that a first surface on which a second sub chip pad is formed faces upwardly, a first connection portion connecting the first sub chip to the second sub chip, and a first redistribution wirings electrically connecting the first sub chip pad to the second sub chip pad;
a plurality of third semiconductor chips sequentially stacked on the first sub chip and arranged to have an offset such that a first surface on which a plurality of third chip pads are formed faces upwardly;
a plurality of fourth semiconductor chips sequentially stacked on the second sub chip and arranged to have an offset such that a first surface on which a plurality of fourth chip pads are formed faces upwardly;
a second double die chip including a third sub chip stacked on an uppermost fourth semiconductor chip among the plurality of fourth semiconductor chips such that a first surface on which a third sub chip pad is formed faces upwardly, a fourth sub chip stacked on an uppermost third semiconductor chip among the plurality of third semiconductor chips such that a first surface on which a fourth sub chip pad is formed faces upwardly, a second connection portion connecting the third sub chip to the fourth sub chip, and a second redistribution wirings electrically connecting the third sub chip pad to the fourth sub chip pad;
a plurality of first conductive connection members electrically connecting the plurality of first substrate pads, the plurality of first chip pads and the first sub chip pad;
a plurality of second conductive connection members electrically connecting the second sub chip pad and the plurality of third chip pads;
a plurality of third conductive connection members electrically connecting the plurality of second substrate pads and the plurality of second chip pads; and
a plurality of fourth conductive connection members electrically connecting the plurality of fourth chip pads and the third sub chip pad.
